(19) United States
(12) Patent Application Publication
(10) Pub. No.: US 2024/0258283 A1
(43) Pub. Date: Aug. 1, 2024

(54) DISPLAY DEVICE AND TILED DISPLAY DEVICE INCLUDING THE SAME

(71) Applicant: Samsung Display Co., LTD., Yongin-si (KR)

(72) Inventors: Jong Duk ROH, Yongin-si (KR); Chan Young PARK, Yongin-si (KR); Kye Uk LEE, Yongin-si (KR); Nak Cho CHOI, Yongin-si (KR)

(73) Assignee: Samsung Display Co., LTD., Yongin-si (KR)

(21) Appl. No.: 18/481,305

(22) Filed: Oct. 5, 2023

(30) Foreign Application Priority Data
Jan. 27, 2023 (KR) 10-2023-0011091

(51) Int. Cl. H01L 25/075; H01L 25/16; H01L 27/15; H01L 33/62

(52) U.S. Cl. CPC H01L 25/0753; H01L 25/167; H01L 27/156; H01L 33/62

(57) ABSTRACT

A display device comprises a substrate comprising a first surface, a second surface opposite to the first surface, a first chamfer surface extending from a side of the first surface, a second chamfer surface extending from a side of the second surface, and a side surface connecting the first chamfer surface to the second chamfer surface, a display area including a plurality of light emitting elements disposed on the first surface of the substrate, a non-display area surrounding the display area on the first surface of the substrate, an engraved pattern portion disposed at a corner portion of the non-display area and recessed from an upper surface of the non-display area, and a trench portion disposed at a plurality of edge portions of the non-display area to surround the display area and recessed toward the substate.

### CROSS-REFERENCE TO RELATED APPLICATION(S)

This application claims priority to and benefits of Korean Patent Application No. 10-2023-0011091 under 35 U.S.C. § 119, filed on Jan. 27, 2023, in the Korean Intellectual Property Office, the entire contents of which are incorporated herein by reference.

### BACKGROUND

### 1. Technical Field

Embodiments relate to a display device and a tiled display device including the display device.

### 2. Description of the Related Art

With the advance of information-oriented society, more demands are placed on display devices for displaying images in various ways. For example, display devices are implemented as various electronic devices such as smartphones, digital cameras, laptop computers, navigation devices, and smart televisions. The display device may be a flat panel display device such as a liquid crystal display device, a field emission display device and an organic light emitting display device. Among the flat panel display devices, in the light emitting display device, since each of pixels of a display panel includes a light emitting element capable of emitting light by itself, an image can be displayed without a backlight unit providing light to the display panel.

When the display device is manufactured in a large size, a defect rate of the light emitting element may increase due to an increase in the number of pixels, thereby deteriorating productivity or reliability of the display device. To solve this problem, in a tiled display device, a large-sized screen may be implemented by connecting a plurality of display devices having a relatively small size. The tiled display device may include a boundary portion as a seam between the plurality of display devices, due to a non-display area or a bezel area of each of the plurality of display devices adjacent to each other. In case that a single image is displayed on the entire screen, the boundary portion between the plurality of display devices causes a sense of discontinuity over the entire screen, thereby reducing a sense of immersion in the image.

### SUMMARY

Embodiments provide a tiled display device capable of preventing incomplete peeling of a front protective film during a manufacturing process of a plurality of display devices.

Embodiments also provide a tiled display device capable of removing a sense of discontinuity between a plurality of display devices and improving immersion of an image by preventing the recognition of a coupling region between a plurality of display devices.

However, embodiments of the disclosure are not limited to those set forth herein. The above and other embodiments will become more apparent to one of ordinary skill in the art to which the disclosure pertains by referencing the detailed description of the disclosure given below.

According to an embodiment, a display device may include a substrate including a first surface, a second surface opposite to the first surface, a first chamfer surface extending from a side of the first surface, a second chamfer surface extending from a side of the second surface, and a side surface connecting the first chamfer surface to the second chamfer surface, a display area including a plurality of light emitting elements disposed on the first surface of the substrate, a non-display area surrounding the display area on the first surface of the substrate, an engraved pattern portion disposed at a corner portion of the non-display area and recessed from an upper surface of the non-display area, and a trench portion disposed at a plurality of edge portions of the non-display area to surround the display area and recessed toward the substrate.

The display device may further include a front pad portion disposed at a part of the plurality of edge portions of the non-display area and electrically connected to the plurality of light emitting elements, a rear pad portion disposed at an edge portion of the second surface of the substrate, and a side surface connection line disposed on a side surface of the substrate and electrically connecting the front pad portion to the rear pad portion.

The display device may further include an antistatic circuit disposed at an edge portion of the display area. The trench portion may be disposed between the front pad portion and the antistatic circuit.

The trench portion may be disposed between the front pad portion and the plurality of light emitting elements. A height of the trench portion may be lower than a height of the front pad portion and a height of each of the plurality of light emitting elements.

The display device may further include a circuit board disposed on the second surface of the substrate and electrically connected to the rear pad portion.

The trench portion may include a plurality of trench portions disposed at each of the plurality of edge portions of the non-display area. The engraved pattern portion may be disposed between adjacent trench portions among the plurality of trench portions.

The display device may further include a thin film transistor layer disposed on the first surface of the substrate and including a pixel circuit connected to a plurality of pixels. The engraved pattern portion may be formed by recessing a part of the thin film transistor layer.

The display device may further include a thin film transistor layer disposed on the first surface of the substrate and including a pixel circuit connected to a plurality of pixels. The engraved pattern portion may be formed by recessing parts of the substrate and the thin film transistor layer.

The display device may further include an antistatic layer disposed at an edge portion of the non-display area and electrically connected to a low potential line or a common voltage line. The trench portion may be disposed between the antistatic layer and a plurality of pixels.

The engraved pattern portion may include at least one of bird's foot shape, a spread shape, a fan-out shape, a wave shape, a parabolic shape, a needle hole shape.

According to an embodiment, a display device may include a substrate, a thin film transistor layer disposed on the substrate, a light emitting element disposed on the thin film transistor layer, a display area including the light emitting element, a non-display area surrounding the display area and including a plurality of edge portions, an engraved pattern portion disposed at least one edge portion of the plurality of edge portions of the non-display area and recessed from an upper surface of the thin film transistor layer, and a trench portion disposed at the plurality of edge portions of the non-display area to surround the display area and recessed toward the substrate.

The display device may further include a front pad portion disposed at a portion of the plurality of edge portions of the non-display area and electrically connected to the light emitting element, and an antistatic circuit disposed at an edge portion of the display area. The trench portion may be disposed between the front pad portion and the antistatic circuit.

The trench portion may be disposed between the front pad portion and the light emitting element. A height of the trench portion may be lower than a height of the front pad portion and a height of the light emitting element.

The trench portion may include a plurality of trench portions disposed at each of the plurality of edge portions of the non-display area. The engraved pattern portion may be disposed between the plurality of trench portions.

The display device may further include a thin film transistor layer disposed on a first surface of the substrate and including a pixel circuit connected to a plurality of pixels. The engraved pattern portion may be formed by recessing a part of the thin film transistor layer.

The display device may further include a thin film transistor layer disposed on a first surface of the substrate and including a pixel circuit connected to a plurality of pixels. The engraved pattern portion may be formed by recessing parts of the substrate and the thin film transistor layer.

The display device may further include a thin film transistor layer disposed on the first surface of the substrate and including a pixel circuit connected to the plurality of pixels, wherein the engraved pattern portion is formed by recessing parts of the substrate and the thin film transistor layer.

According to an embodiment, a tiled display device may include a plurality of display devices that display an image, and a coupling area disposed between the plurality of display devices. At least one of the plurality of display devices may include a substrate including a first surface, a second surface opposite to the first surface, a first chamfer surface extending from a side of the first surface, a second chamfer surface extending from a side of the second surface, and a side surface connecting the first chamfer surface to the second chamfer surface, a display area including a plurality of light emitting elements disposed on the first surface of the substrate, a non-display area surrounding the display area on the first surface of the substrate, an engraved pattern portion disposed at a corner portion of the non-display area and recessed from an upper surface of the non-display area, and a trench portion disposed at a plurality of edge portions of the non-display area to surround the display area and recessed toward the substrate.

Each of the plurality of light emitting elements may be a micro light emitting diode of a flip chip type.

At least one of the plurality of display devices may further include a front pad portion disposed at a part of the plurality of edge portions of the non-display area and electrically connected to the plurality of light emitting elements, a rear pad portion disposed at an edge portion of the second surface of the substrate, a side surface connection line disposed on a side surface of the substrate and electrically connecting the front pad portion to the rear pad portion, and a circuit board disposed on the second surface of the substrate and electrically connected to the rear pad portion.

The plurality of display devices may be arranged in a matrix form in M rows and N columns, where M and N may be positive integers.

According to the display device and the tiled display device including the display device, by disposing corner portion of the front protective film in an engraved pattern portion, a contact angle of the corner portion of the front protective film may rise and peeling force of the front protective film may be dispersed. Accordingly, the engraved pattern portion can prevent incomplete peeling of the front protective film, and the front protective film may be readily peeled off from the display device, thereby improving reliability of the display device.

According to the display device and the tiled display device including the display device, by minimizing the space between the plurality of display devices, the coupling region may be prevented from being recognized by the user, thereby removing a sense of discontinuity between the plurality of display devices and improving a sense of immersion in the image.

It should be noted that the effects of the disclosure are not limited to those described above, and other effects of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic plan view illustrating a tiled display device according to an embodiment;

FIG. 2 is a schematic plan view illustrating a display device according to an embodiment;

FIG. 3 is a schematic rear view showing a display device according to an embodiment;

FIG. 4 is a schematic perspective view showing an edge portion of a display device according to an embodiment;

FIG. 5 is a schematic plan view showing an edge portion of a display device of FIG. 4;

FIG. 6 is a schematic rear view showing an edge portion of a display device of FIG. 4;

FIG. 7 is a schematic cross-sectional view taken along line I-I′ of FIG. 5;

FIG. 8 is a schematic cross-sectional view taken along line II-II′ of FIG. 6;

FIG. 9 is a schematic perspective view of an example of an engraved pattern portion in a display device according to an embodiment;

FIG. 10 is a schematic perspective view of another example of an engraved pattern portion in a display device according to an embodiment;

FIG. 11 is a schematic perspective view of yet another example of an engraved pattern portion in a display device according to an embodiment;

FIG. 12 is a schematic perspective view of still yet another example of an engraved pattern portion in a display device according to an embodiment;

FIG. 13 is a schematic perspective view of still yet another example of an engraved pattern portion in a display device according to an embodiment;

FIG. 14 is a schematic flowchart illustrating a process for manufacturing a display device according to an embodiment;

FIG. 15 is a schematic cross-sectional view taken along line of FIG. 9, showing a process for manufacturing a display device according to an embodiment;

FIG. 16 shows a schematic cross-sectional view illustrating a process of removing a front protective film in a manufacturing process of a display device of FIG. 15;

FIG. 17 is a schematic cross-sectional view taken along line of FIG. 9, showing a process for manufacturing a display device according to an embodiment;

FIG. 18 is an enlarged schematic view of region Al of FIG. 1;

FIG. 19 is a schematic cross-sectional view taken along line IV-IV′ of FIG. 18; and

FIG. 20 is a schematic block diagram illustrating a display system according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed by using semiconductor-based fabrication techniques or other manufacturing technologies. In the case of the blocks, units, parts, and/or modules being implemented by microprocessors or other similar hardware, they may be programmed and controlled by using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the invention. Further, the blocks, units, parts, and/or modules of some embodiments may be physically combined into more complex blocks, units, parts, and/or modules without departing from the scope of the invention.

Hereinafter, detailed embodiments of the disclosure is described with reference to the accompanying drawings.

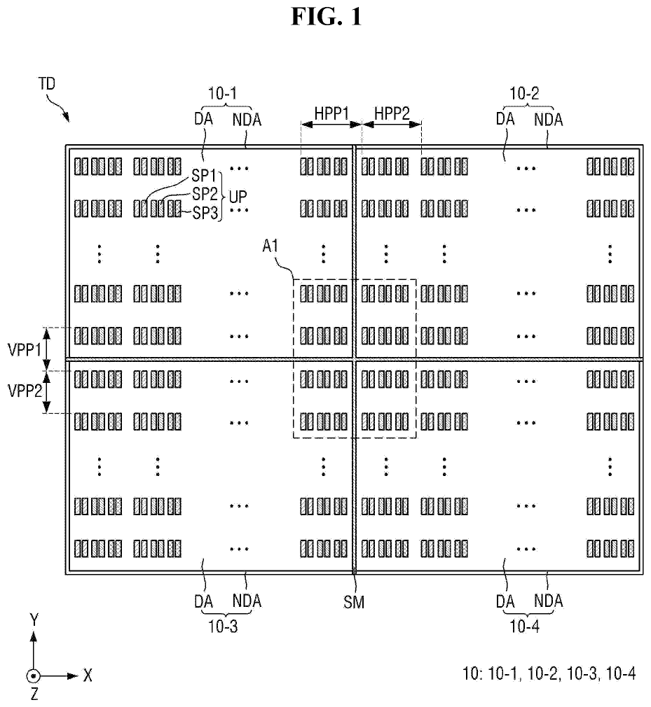

FIG. 1 is a schematic plan view illustrating a tiled display device according to an embodiment.

Referring to FIG. 1, a tiled display device TD may include display devices 10. The display devices 10 may be arranged in a grid form, but embodiments are not limited thereto. The display devices 10 may be connected in a first direction (e.g., X-axis direction) or a second direction (e.g., Y-axis direction), and the tiled display device TD may have a certain shape. For example, the display devices 10 may have the same size, but embodiments are not limited thereto. For another example, the display devices 10 may have different sizes.

The tiled display device TD may include first to fourth display devices 10-1 to 10-4. The number and connection relationship of the display devices 10 are not limited to the embodiment of FIG. 1. The number of the display devices 10 may be determined according to the size of each of the display devices 10 and the tiled display device TD.

The display devices 10 may be arranged in a matrix form in M rows and N columns, where M and N are positive integers. Each of the display devices 10 may have a rectangular shape including long sides and short sides. The display devices 10 may be arranged such that the long sides or the short sides thereof are connected to each other. Some of the display devices 10 may be disposed at the edge portion of the tiled display device TD to form a side of the tiled display device TD. Some others of the display devices 10 may be disposed at corner portions of the tiled display device TD to form two adjacent sides of the tiled display device TD. Yet some others of the display devices 10 may be disposed on the inner side of the tiled display device TD, and may be surrounded by other display devices 10.

Each of the display devices 10 may include a display area DA and a non-display area NDA. The display area DA may include unit pixels UP to display an image. Each of the unit pixels UP may include first to third pixels SP1, SP2, and SP3. Each of the first to third pixels SP1, SP2 and SP3 may include an organic light emitting diode including an organic light emitting layer, a quantum dot LED including a quantum dot light emitting layer, an inorganic LED including an inorganic semiconductor, or a micro LED. In the following, the case where each of the first to third pixels SP1, SP2, and SP3 includes a micro LED will be described, but embodiments are not limited thereto. The non-display area NDA may be disposed around the display area DA to surround the display area DA, and may not display an image.

The display device 10 may include the unit pixels UP arranged along rows and columns in the display area DA. The unit pixel UP may include the first to third pixels SP1, SP2, and SP3. Each of the first to third pixels SP1, SP2, and SP3 may include an emission area or an opening area defined by a pixel defining film or a bank, and may emit light having a certain peak wavelength through the emission area or the opening area. The emission area may be an area in which light generated by a light emitting element of the display device 10 is emitted to the outside of the display device 10. The first pixel SP1 may emit light of a first color, the second pixel SP2 may emit light of a second color, and the third pixel SP3 may emit light of a third color. For example, the light of the first color may be red light having a peak wavelength in the range of about 610 nm to about 650 nm, the light of the second color may be green light having a peak wavelength in the range of about 510 nm to about 550 nm, and the light of the third color may be blue light having a peak wavelength in the range of about 440 nm to about 480 nm, but embodiments are not limited thereto.

The first to third pixels SP1, SP2, and SP3 may be sequentially and repeatedly disposed along the first direction (e.g., X-axis direction) of the display area DA. As an example, areas of the emission areas of the first to third pixels SP1, SP2, and SP3 may be substantially the same as each other, but embodiments are not limited thereto. As another example, areas of the emission areas of the first to third pixels SP1, SP2, and SP3 may be different from each other.

The tiled display device TD may have an overall planar shape, but embodiments are not limited thereto. The tiled display device TD may have a three-dimensional shape to provide a three-dimensional effect to a user. As an example, in case that the tiled display device TD has the three-dimensional shape, at least some of the display devices 10 may have a curved shape. As another example, the display devices 10 may have a planar shape and may be connected to each other at a certain angle, such that the tiled display device TD may have a three-dimensional shape.

The tiled display device TD may include coupling areas SM disposed between the display areas DA. The tiled display device TD may be formed by connecting the non-display areas NDA of each of adjacent display devices 10 to each other. The display devices 10 may be connected to each other through coupling members or adhesive members disposed in the coupling areas SM. The coupling areas SM of each of the display devices 10 may not include pad parts or flexible films attached to the pad parts. A distance between the display areas DA of each of the display devices 10 may be too small for the coupling areas SM between the display devices 10 to be recognized by the user. For example, a first horizontal pixel pitch HPP1 between pixels of the first display device 10-1 and pixels of the second display device 10-2 may be substantially the same as a second horizontal pixel pitch HPP2 between pixels of the second display device 10-2. A first vertical pixel pitch VPP1 between pixels of the first display device 10-1 and pixels of the third display device 10-3 may be substantially the same as a second vertical pixel pitch VPP2 between pixels of the third display device 10-3. Accordingly, the tiled display device TD may remove (or minimized) a sense of discontinuity between the display devices 10 and improve a degree of immersion of an image by preventing the coupling areas SM between the display devices 10 from being recognized by the user.

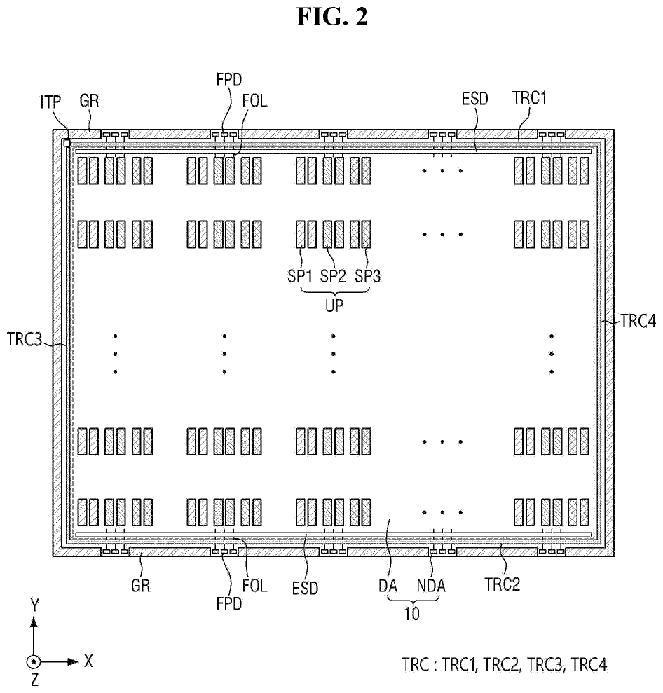

FIG. 2 is a schematic plan view illustrating a display device according to an embodiment.

Referring to FIG. 2, the display device 10 may include a display area DA and a non-display area NDA. The display area DA may include unit pixels UP, antistatic circuits ESD, and fan-out lines FOL.

The unit pixels UP may be arranged to have a uniform pixel pitch. The unit pixels UP may be arranged along pixel rows and pixel columns. The unit pixel UP may include first to third pixels SP1, SP2, and SP3. Each of the first to third pixels SP1, SP2, and SP3 of FIG. 2 may correspond to at least one light emitting element exposed by the opening area. As an example, each of the first to third pixels SP1, SP2, and SP3 may include two light emitting elements. For example, each of the first to third pixels SP1, SP2, and SP3 may include a main light emitting element and a repair light emitting element, but embodiments are not limited thereto. As another example, each of the first to third pixels SP1, SP2, and SP3 may include three or more light emitting elements. Accordingly, the first to third pixels SP1, SP2, and SP3 may emit light corresponding to gradations of the corresponding pixels.

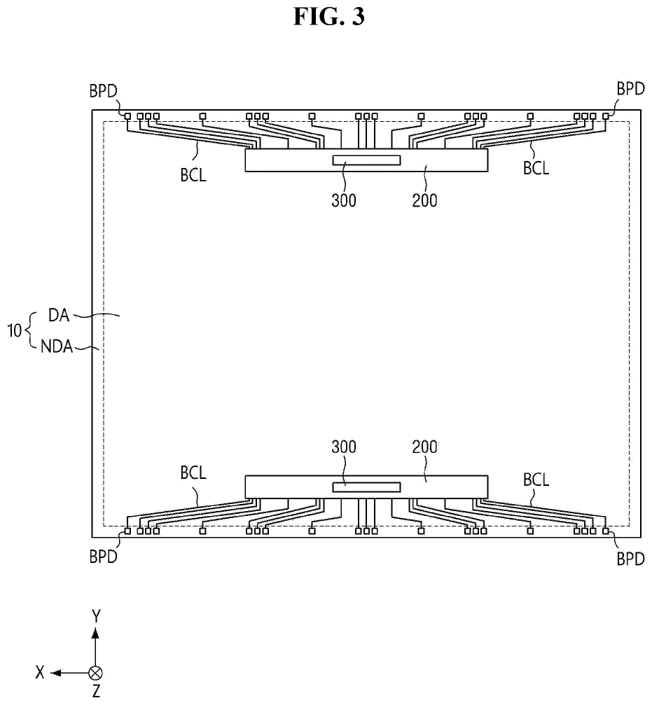

The antistatic circuits ESD may be disposed at an upper edge portion (or upper side portion) and lower edge portion (or lower side portion) of the display area DA, but embodiments are not limited thereto. The antistatic circuits ESD may be disposed adjacent to the fan-out lines FOL electrically connected to circuit board (‘300’ of FIG. 3). For example, in case that the fan-out lines FOL are disposed at the upper and lower edge portions of the display area DA, the antistatic circuits ESD may be disposed at the upper and lower edge portions of the display area DA. The antistatic circuits ESD may eliminate static electricity introduced (or transferred) from the outside to prevent the static electricity from being introduced (or transferred) into the display area DA through the fan-out lines FOL.

The fan-out lines FOL may extend from the antistatic circuits ESD to the unit pixels UP. The fan-out lines FOL may be disposed at the upper and lower edge portions of the display area DA, but embodiments are not limited thereto. The fan-out lines FOL may be electrically connected to the unit pixels UP of the display area DA. The fan-out lines FOL may be electrically connected to the circuit board through a front pad portion FPD. The fan-out lines FOL may supply voltages or signals received from the front pad portion FPD to the display area DA. For example, the fan-out lines FOL may be electrically connected to data lines, clock lines, or power lines disposed in the display area DA. For example, the power lines may be driving voltage lines, low potential lines, initialization voltage lines, reference voltage lines, gate high voltage lines, or gate low voltage lines, but embodiments are not limited thereto.

The non-display area NDA may include the front pad portion FPD, an antistatic layer GR, an engraved pattern portion ITP, and a trench portion TRC.

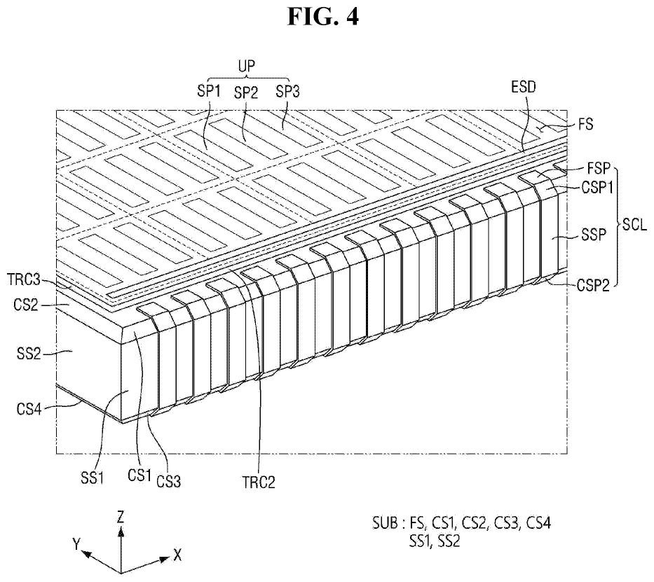

The front pad portion FPD may be disposed at edge portions of the non-display area NDA. The front pad portion FPD may be disposed at upper and lower edge portions of the non-display area NDA, but embodiments are not limited thereto. The front pad portion FPD may be disposed between the antistatic layers GR. The front pad portion FPD may not overlap the antistatic layers GR in a third direction (e.g., Z-axis direction) or a thickness direction. The front pad portions FPD may be electrically connected to the circuit board through side surface connection lines (‘SCL’ of FIG. 4), rear pad portions (‘BPD’ of FIG. 3), and lead lines (‘BCL’ of FIG. 3). For example, the front pad portions FPD may be test pads receiving test signals, but embodiments are not limited thereto.

The antistatic layers GR may be disposed at edge portions of an upper surface of the display device 10 or edge portions of an upper portion of a substrate to surround the display area DA. The antistatic layers GR may be disposed at a portion of an upper edge portion, a portion of a lower edge portion, a left edge portion, and a right edge portion of the non-display area NDA. The antistatic layers GR may not be disposed on portions of the upper and lower edge portions of the non-display area NDA, and thus, may not overlap the front pad portion FPD in the third direction (e.g., Z-axis direction) or the thickness direction. The antistatic layers GR may be guard rings capable of preventing static electricity, but embodiments are not limited thereto. The antistatic layers GR may be electrically connected to a low potential line or a common voltage line to rapidly discharge static electricity. For example, the low potential line or the common voltage line may receive a low potential voltage or a common voltage. The antistatic layers GR may be disposed at the edge portions of the upper surface of the display device 10 and may eliminate static electricity introduced (or transferred) in a cutting process or a grinding process of the display device 10 to prevent the static electricity from being introduced (or transferred) into the display area DA. The antistatic layers GR may rapidly discharge static electricity introduced (or transferred) from the outside of the display device 10.

As an example, the antistatic layer GR may include a transparent conductive material (TCO) such as indium tin oxide (ITO), indium zinc oxide (IZO), or indium tin zinc oxide (ITZO). As another example, the antistatic layer GR may have a stacked structure such as ITO/Ag/ITO/, ITO/Ag/IZO, or ITO/Ag/ITZO/IZO. As still another example, the antistatic layer GR may include at least one of molybdenum (Mo), aluminum (Al), chromium (Cr), gold (Au), titanium (Ti), nickel (Ni), neodymium (Nd), and copper (Cu).

The engraved pattern portion ITP may be disposed at a corner portion of the non-display area NDA. The engraved pattern portion ITP may be formed to be recessed from the top surface of the non-display area NDA. For example, the engraved pattern portion ITP may be formed by recessing a part of the thin film transistor layer. In another example, the engraved pattern portion ITP may be formed by recessing a part of a substrate. The engraved pattern portion ITP may be disposed at the upper left corner portion of the display device 10, but embodiments are not limited thereto. The engraved pattern portion ITP may be disposed at least at one of the corner portions of the display device 10.

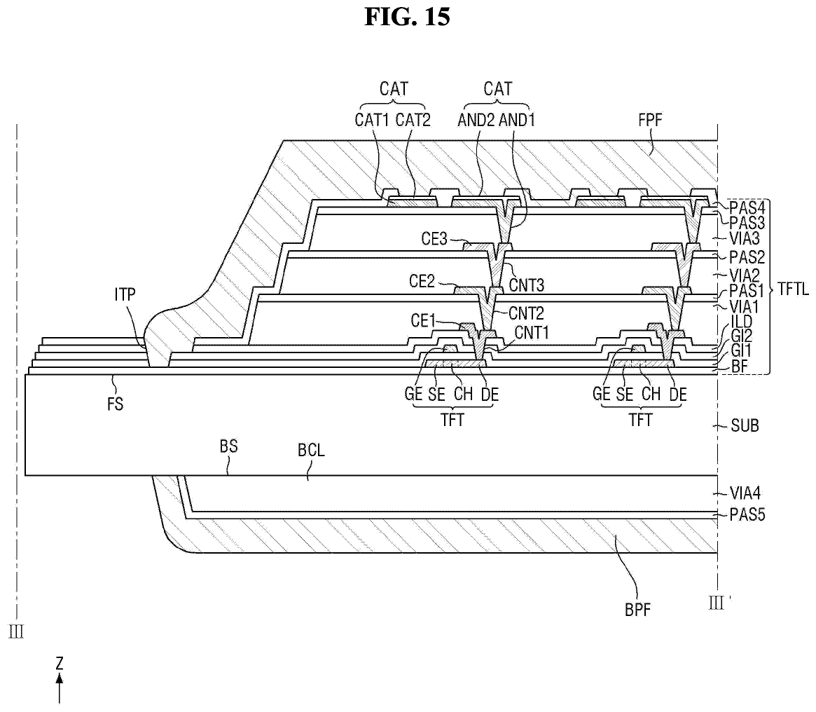

In the process of removing a front protective film (‘FPF’ of FIG. 15) of the display device 10, the engraved pattern portion ITP may be disposed at a starting point of peeling of the front protective film. For example, the front protective film may protect the front surface of the display device 10 during the manufacturing process of the display device 10. In case that the engraved pattern portion ITP does not exist, the thickness of the edge portion of the front protective film may be reduced, and the front protective film may be incompletely peeled off, so that a part of the front protective film may remain. Remaining or unpeeled portions of the front protective film may degrade reliability of the display device 10. The corner portion of the front protective film may be inserted into the engraved pattern portion ITP. As the engraved pattern portion ITP accommodates the corner portion of the front protective film, the thickness of the corner portion of the front protective film may be increased. For example, as the thickness of the corner portion or the edge portion of the front protective film increases, the contact angle may increase and the surface tension may decrease. Accordingly, since the corner portion of the front protective film is disposed in the engraved pattern portion ITP, the contact angle of the corner portion of the front protective film may be increased and the release force of the front protective film may be dispersed. The engraved pattern portion ITP may prevent incomplete peeling of the front protective film, and the front protective film may be readily peeled off from the display device 10.

The trench portion TRC may be disposed at the edge portions of the non-display area NDA and have a trench structure that is more recessed than the surrounding area. The trench portion TRC may have a trench structure between the front pad portion FPD and the antistatic circuit ESD. The trench portion TRC may have a trench structure between the antistatic layer GR and the unit pixels UP. Edge portions of the front protective film may be inserted into the trench portions TRC. The trench portion TRC may increase the thickness of the edge portions of the front protective film by accommodating the edge portions of the front protective film. Accordingly, since the edge portions of the front protective film are disposed in the trench portions TRC, the contact angle of the edge portions of the front protective film may increase, and the release force of the front protective film may be dispersed. The trench portion TRC may prevent incomplete peeling of the front protective film, and the front protective film may be readily peeled from the display device 10.

The trench portion TRC may include first to fourth trench portions TRC1, TRC2, TRC3, and TRC4. The first trench portion TRC1 may be disposed above the non-display area NDA, the second trench portion TRC2 may be disposed below the non-display area NDA, the third trench portion TRC3 may be disposed on the left side of the non-display area NDA, and the fourth trench portion TRC4 may be disposed on the right side of the non-display area NDA, but embodiments are not limited thereto. The first to fourth trench portions TRC1, TRC2, TRC3, and TRC4 may surround the display area DA. Accordingly, the edge portions of the front protective film may be inserted into the first to fourth trench portions TRC1, TRC2, TRC3, and TRC4, so that the unit pixels UP may be stably protected during the manufacturing process of the display device 10. The engraved pattern portion ITP may be disposed at an intersection of an extension line of the first trench portion TRC1 and an extension line of the third trench portion TRC3, but embodiments are not limited thereto. For another example, the engraved pattern portion ITP may be disposed between adjacent trench portions TRC among the first to fourth trench portions TRC1, TRC2, TRC3, and TRC4.

FIG. 3 is a schematic rear view showing a display device according to an embodiment.

Referring to FIG. 3, the display device 10 may include a display area DA and a non-display area NDA. The display area DA may include a circuit board 200, a display driver 300, and lead lines BCL.

The circuit board 200 may be disposed on the rear surface of the display device 10. The circuit board 200 may be attached to the bottom surface of the display device 10 through an adhesive member or an anisotropic conductive film. The circuit board 200 may supply a voltage or signal to fan-out lines FOL disposed on the top portion of the substrate through the lead line BCL, the rear pad portion BPD, a side surface connection line, and the front pad portion FPD. For example, the circuit board 200 disposed above the display area DA may supply a voltage or signal to a fan-out line FOL disposed above the display area DA, and the circuit board 200 disposed below the display area DA may supply a voltage or signal to the fan-out line FOL disposed below the display area DA. The circuit board 200 may transmit a signal of the display driver 300 to the display device 10.

The display driver 300 may output signals and voltages for driving the first to third pixels SP1, SP2, and SP3. The display driver 300 may supply data voltages to data lines. The data voltage may be supplied to the first to third pixels SP1, SP2, and SP3 to determine the luminance of the first to third pixels SP1, SP2, and SP3. The display driver 300 may supply a power voltage to the power line and may supply a clock signal to the gate driver. For example, the display driver 300 may be formed of an integrated circuit (IC) and mounted on the circuit board 200 by a chip on film method or a tape carrier package method, but embodiments are not limited thereto.

The lead lines BCL may extend from the circuit board 200 disposed in the display area DA to an edge portion of the non-display area NDA. The lead lines BCL may be disposed on the upper and lower edge portions of the lower surface of the display device 10, but embodiments are not limited thereto. The lead line BCL may supply a voltage or a signal received from the circuit board 200 to the fan-out line FOL through the rear pad portion BPD, the side surface connection line, and the front pad portion FPD. For example, the lead line BCL disposed above the display area DA may be electrically connected to the fan-out line FOL disposed above the display area DA, and the lead line BCL disposed below the display area DA may be electrically connected to the fan-out line FOL disposed below the display area DA.

In the display device 10, the circuit board 200 and the display drivers 300 may be disposed on the lower surface of the display device 10, and thus, may not be disposed in the coupling areas SM of the tiled display device TD. Accordingly, the non-display area NDA of the display device 10 may be minimized, and a pixel pitch between adjacent display devices 10 may be designed to be the same as a pixel pitch in the display device 10. The display device 10 may include the antistatic layers GR, and may thus eliminate static electricity introduced (or transferred) from the outside of the display device 10 to prevent damage to a thin film transistor layer and a light emitting element layer.

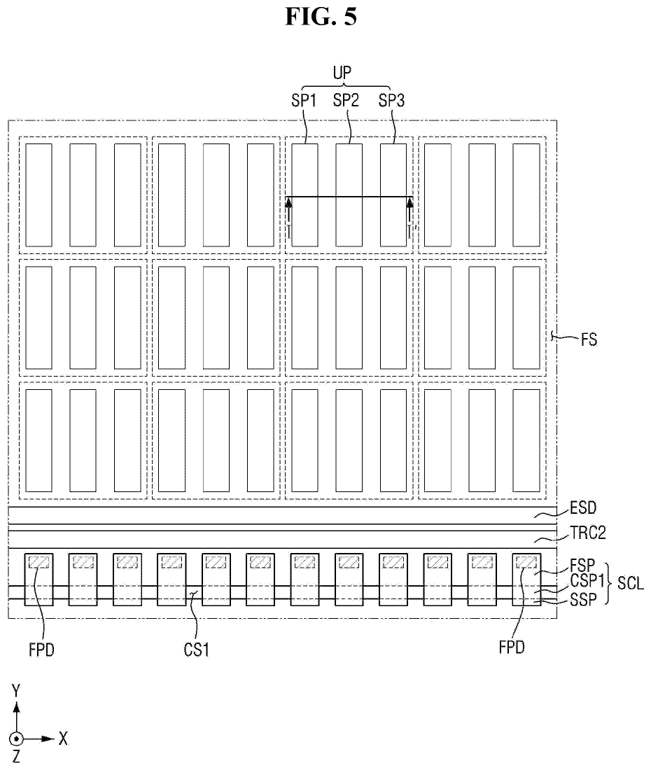

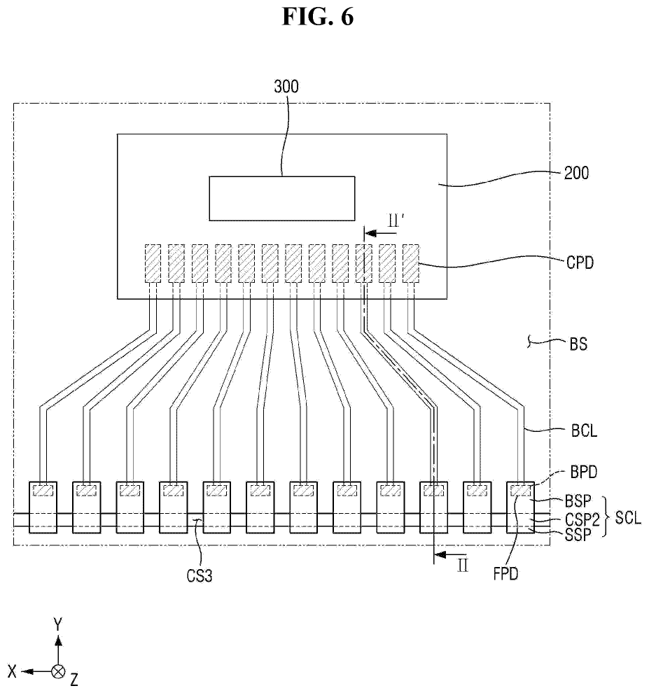

FIG. 4 is a schematic perspective view showing an edge portion of a display device according to an embodiment, FIG. 5 is a schematic plan view showing an edge portion of a display device of FIG. 4, and FIG. 6 is a schematic rear view showing an edge portion of a display device of FIG. 4.

Referring to FIGS. 4 to 6, the display device may include a substrate SUB, the front pad portions FPD, the side surface connection lines SCL, the rear pad portions BPD, lead lines BCL, and contact pad portions CPD.

The substrate SUB may include a first surface FS, a second surface BS, first to fourth chamfer surfaces CS1, CS2, CS3, and CS4, and first and second side surfaces SS1 and SS2.

The first surface FS may be the front surface of the substrate SUB. The first surface FS may have a rectangular shape having long sides in the first direction (e.g., X-axis direction) and short sides in the second direction (e.g., Y-axis direction).

The second surface BS may be the rear surface of the substrate SUB, and face the first surface FS. The second surface BS may have a rectangular shape having long sides in the first direction (e.g., X-axis direction) and short sides in the second direction (e.g., Y-axis direction).

The first to fourth chamfer surfaces CS1, CS2, CS3, and CS4 may be formed by obliquely cutting the substrate SUB by a chamfer process. As the first chamfer surface CS1 is disposed between the first surface FS and the first side surface SS1, the second chamfer surface CS2 is disposed between the first surface FS and the second side surface SS2, the third chamfer surface CS3 is disposed between the second surface BS and the first side surface SS1, and the fourth chamfer surface CS4 is disposed between the second surface BS and the second side surface SS2, it is possible to prevent occurrence of chipping defects. As the first to fourth chamfer surfaces CS1, CS2, CS3, and CS4 gently form the bending angle of the side surface connection line SCL, it is possible to prevent chipping or cracking of the side surface connection line SCL. An interior angle formed by the first surface FS and the first chamfer surface CS1, an interior angle formed by the first surface FS and the second chamfer surface CS2, an interior angle formed by the second surface BS and the third chamfer surface CS3, and an interior angle formed by the second surface BS and the fourth chamfer surface CS4 may be greater than 90 degrees.

The first side surface SS1 may be disposed between the first chamfer surface CS1 and the third chamfer surface CS3. The first side surface SS1 may be a lower surface of the substrate SUB.

The second side surface SS2 may be disposed between the second chamfer surface CS2 and the fourth chamfer surface CS4. The second side surface SS2 may be the left side surface of the substrate SUB.

The front pad portion FPD may be disposed on the first surface FS of the substrate SUB. The front pad portion FPD may be disposed on upper and lower edge portions of the first surface FS of the substrate SUB. The front pad portion FPD may be arranged in the first direction (e.g., X-axis direction). The front pad portion FPD may be electrically connected to the rear pad portion BPD through the side surface connection line SCL. A front pad portion FPD may be electrically connected to one rear pad portion BPD through a side surface connection line SCL. For another example, at least one front pad portion FPD may be electrically connected to at least one rear pad portion BPD through at least one side surface connection line SCL. The front pad portion FPD may be electrically connected to the data line of the display area DA to supply a data voltage. The front pad portion FPD may be connected to a power line or a power electrode of the display area DA to supply a power voltage. For example, the power voltage may be a high potential voltage or a low potential voltage for driving the unit pixel UP, but embodiments are not limited thereto.

The side surface connection line SCL may be disposed on the side surface of the substrate SUB to electrically connect the front pad portion FPD and the rear pad portion BPD. The side surface connection line SCL may include a front portion FSP, a first chamfer portion CSP1, a side portion SSP, a second chamfer portion CSP2, and a rear portion BSP.

The front portion FSP may be disposed on the first surface FS of the substrate SUB. The front portion FSP may be disposed on the front pad portion FPD to cover (e.g., completely cover) the front pad portion FPD. The front portion FSP may be connected to the front pad portion FPD.

The first chamfer portion CSP1 may be disposed on the first chamfer surface CS1 of the substrate SUB. The first chamfer portion CSP1 may be disposed between the front portion FSP and the side portion SSP.

The side portion SSP may be disposed on the first side surface SS1 of the substrate SUB. The side portion SSP may be disposed between the first chamfer portion CSP1 and the second chamfer portion CSP2.

The second chamfer portion CSP2 may be disposed on the third chamfer surface CS3 of the substrate SUB. The second chamfer portion CSP2 may be disposed between the side portion SSP and the rear portion BSP.

The rear portion BSP may be disposed on the second surface BS of the substrate SUB. The rear portion BSP may be disposed on the rear pad portion BPD to cover (e.g., completely cover) the rear pad portion BPD. The rear portion BSP may be connected to the rear pad portion BPD.

The side surface connection line SCL may include metal powder and polymer. For example, the metal powder may include metal particles such as silver (Ag) and copper (Cu), and the polymer may include an acrylic resin or an epoxy resin, but embodiments are not limited thereto. The side surface connection line SCL may have conductivity by including the metal powder, and may serve as a binder connecting the metal particles by including the polymer.

For example, the side surface connection line SCL may be formed by printing a metal paste including metal particles, a monomer, and a solvent on the substrate SUB by using a silicon pad and sintering by using a laser. The side surface connection line SCL may have a lower resistance as the metal particles adhere to each other and agglomerate in case that the monomer reacts to the polymer by the heat generated by the laser in the sintering process.

The rear pad portion BPD may be disposed on the second surface BS of the substrate SUB. The rear pad portion BPD may be disposed on upper and lower edge portions of the second surface BS of the substrate SUB. The rear pad portion BPD may be arranged in the first direction (e.g., X-axis direction). The rear pad portion BPD may be electrically connected to the contact pad portion CPD through the lead line BCL. The rear pad portion BPD may supply the data voltage received from the display driver 300 to the front pad portion FPD. The rear pad portion BPD may supply the power voltage received from the circuit board 200 to the front pad portion FPD.

The lead line BCL may electrically connect the rear pad portion BPD and the contact pad portion CPD. The lead line BCL may be integral with the rear pad portion BPD and the contact pad portion CPD, but embodiments are not limited thereto. The rear pad portion BPD, the lead line BCL, and the contact pad portion CPD may include at least one of molybdenum (Mo), aluminum (Al), chromium (Cr), gold (Au), titanium (Ti), nickel (Ni) , neodymium (Nd) and copper (Cu).

The contact pad portion CPD may be disposed on the second surface BS of the substrate SUB. The contact pad portion CPD may be closer to the center of the second surface BS than the rear pad portion BPD. The contact pad portions CPD may be arranged in a first direction (e.g., X-axis direction). The interval (or distance) between the contact pad portions CPD adjacent to each other in the first direction (e.g., X-axis direction) may be smaller than the interval (or distance) between the rear pad portions BPD adjacent to each other in the first direction (e.g., X-axis direction), and greater number of contact pad portions CPD may be connected to the circuit board 200. The contact pad portion CPD may be electrically connected to the circuit board 200 through a conductive adhesive member. The contact pad portion CPD may supply a data voltage received from the display driver 300 to the rear pad portion BPD. The contact pad portion CPD may supply the power voltage from the circuit board 200 to the rear pad portion BPD.

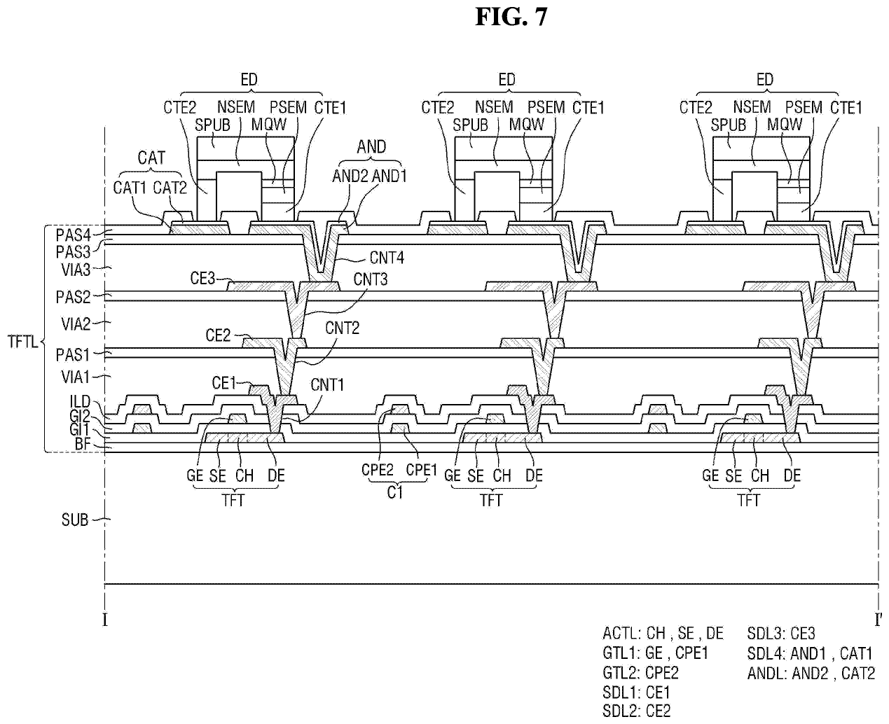

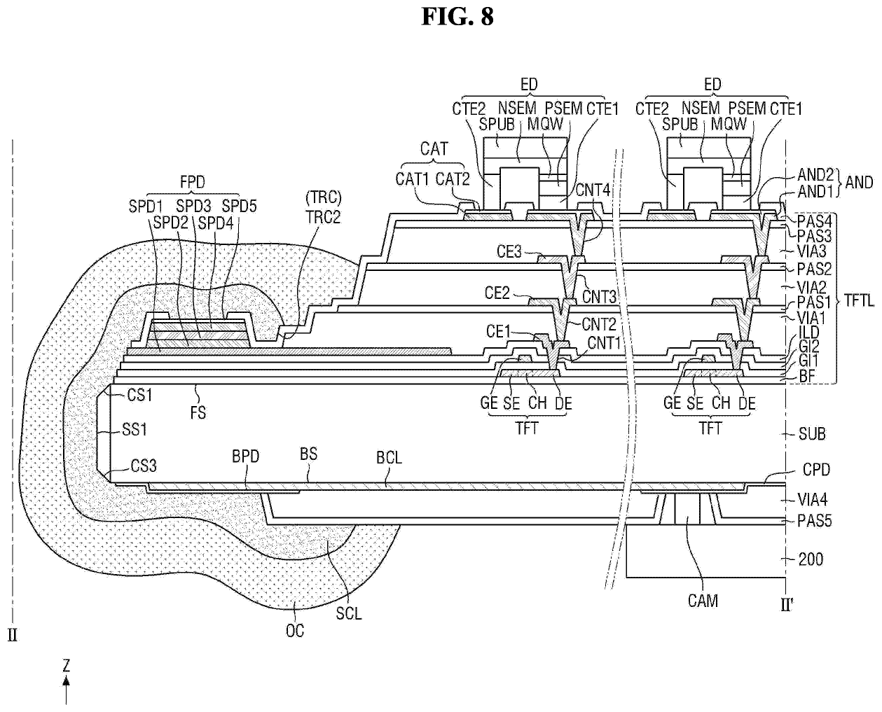

FIG. 7 is a schematic cross-sectional view taken along line I-I′ of FIG. 5, and FIG. 8 is a schematic cross-sectional view taken along line II-II′ of FIG. 6.

Referring to FIGS. 7 and 8, the display device 10 may include the substrate SUB, a buffer layer BF, an active layer ACTL, a first gate insulating layer GI1, a first gate layer GTL1, a second gate insulating layer GI2, a second gate layer GTL2, an interlayer insulating layer ILD, a first source metal layer SDL1, a first via layer VIA1, a first passivation layer PAS1, a second source metal layer SDL2, a second via layer VIA2, a second passivation layer PAS2, a third source metal layer SDL3, a third via layer VIA3, a third passivation layer PAS3, a fourth source metal layer SDL4, an anode layer ANDL, a fourth passivation layer PAS4, the front pad portion FPD, the side surface connection line SCL, the rear pad portion BPD, the contact pad portion CPD, a fourth via layer VIA4, a fifth passivation layer PASS, and the circuit board 200.

The substrate SUB may support the display device 10. The substrate SUB may be a base substrate or a base member. The substrate SUB may be a flexible substrate which can be bent, folded or rolled. For example, the substrate SUB may be a rigid substrate including a glass material, but embodiments are not limited thereto. For another example, the substrate SUB may include an insulating material such as a polymer resin such as polyimide (PI).

The buffer layer BF may be disposed on the substrate SUB. The buffer layer BF may include an inorganic material capable of preventing permeation of air or moisture. The buffer layer BF may include inorganic layers that are alternately stacked. For example, the buffer layer BF may be a multilayer in which one or more inorganic layers of a silicon nitride layer, a silicon oxynitride layer, a silicon oxide layer, a titanium oxide layer and an aluminum oxide layer are alternately stacked.

The active layer ACTL may be disposed on the buffer layer BF. The active layer ACTL may include a channel CH, a source electrode SE, and a drain electrode DE of a thin film transistor TFT. For example, the thin film transistor TFT may be a transistor included in a pixel circuit. The source electrode SE and the drain electrode DE may be made to be conductive by performing heat treatment on the active layer ACTL. For example, the active layer ACTL may include polycrystalline silicon, monocrystalline silicon, low-temperature polycrystalline silicon, amorphous silicon, or an oxide semiconductor. For another example, the active layer ACTL may include first and second active layers disposed on different layers. For example, the first active layer may include polycrystalline silicon, monocrystalline silicon, low-temperature polycrystalline silicon, or amorphous silicon, and the second active layer may include an oxide semiconductor.

The first gate insulating layer GI1 may be disposed on the active layer ACTL. The first gate insulating layer GI1 may insulate a gate electrode GE and the channel CH of the thin film transistor TFT. The first gate insulating layer GI1 may include an inorganic layer. For example, the first gate insulating layer GI1 may include one of a silicon nitride layer, a silicon oxynitride layer, a silicon oxide layer, a titanium oxide layer, and an aluminum oxide layer.

The first gate layer GTL1 may be disposed on the first gate insulating layer GI1. The first gate layer GTL1 may include the gate electrode GE of the thin film transistor TFT, and a first capacitor electrode CPE1 of a first capacitor C1. The first gate layer GTL1 may be a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second gate insulating layer GI2 may be disposed on the first gate layer GTL1. The second gate insulating layer GI2 may insulate the first gate layer GTL1 and the second gate layer GTL2. The second gate insulating layer GI2 may include an inorganic layer. For example, the second gate insulating layer GI2 may include one of a silicon nitride layer, a silicon oxynitride layer, a silicon oxide layer, a titanium oxide layer, and an aluminum oxide layer.

The second gate layer GTL2 may be disposed on the second gate insulating layer GI2. The second gate layer GTL2 may include a second capacitor electrode CPE2 of the first capacitor C1. The second gate layer GTL2 may be a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The interlayer insulating layer ILD may be disposed on the second gate layer GTL2. The interlayer insulating layer ILD may insulate the first source metal layer SDL1 and the second gate layer GTL2. The interlayer insulating layer ILD may include an inorganic layer. For example, the interlayer insulating layer ILD may include one of a silicon nitride layer, a silicon oxynitride layer, a silicon oxide layer, a titanium oxide layer, and an aluminum oxide layer.

The first source metal layer SDL1 may be disposed on the interlayer insulating layer ILD. The first source metal layer SDL1 may include a first connection electrode CE1. The first connection electrode CE1 may be connected to a second connection electrode CE2 penetrating the first passivation layer PAS1 and the first via layer VIA1. The first connection electrode CE1 may be connected to the drain electrode DE of the thin film transistor TFT with penetrating the interlayer insulating layer ILD, the second gate insulating layer G12, and the first gate insulating layer GI1. Accordingly, the first connection electrode CE1 may electrically connect the second connection electrode CE2 with the drain electrode DE. The first source metal layer SDL1 may be a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The first via layer VIA1 may be disposed on the first source metal layer SDL1. The first via layer VIA1 may flatten the upper end portion of the first source metal layer SDL1. The first via layer VIA1 may include an organic layer such as an acryl resin, an epoxy resin, a phenolic resin, a polyamide resin, a polyimide resin, or the like.

The first passivation layer PAS1 may be disposed on the first via layer VIA1 to protect the first source metal layer SDL1. The first passivation layer PAS1 may include an inorganic layer. For example, the first passivation layer PAS1 may include one of a silicon nitride layer, a silicon oxynitride layer, a silicon oxide layer, a titanium oxide layer, and an aluminum oxide layer.

The second source metal layer SDL2 may be disposed on the first via layer VIA1. The second source metal layer SDL2 may include the second connection electrode CE2. The second connection electrode CE2 may be connected to a third connection electrode CE3 penetrating the second passivation layer PAS2 and the second via layer VIA2. Accordingly, the second connection electrode CE2 may electrically connect the third connection electrode CE3 with the first connection electrode CE1. The second source metal layer SDL2 may be a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second via layer VIA2 may be disposed on the second source metal layer SDL2. The second via layer VIA2 may flatten the upper end portion of the second source metal layer SDL2. The second via layer VIA2 may include an organic layer such as an acryl resin, an epoxy resin, a phenolic resin, a polyamide resin, a polyimide resin, or the like.

The second passivation layer PAS2 may be disposed on the second via layer VIA2 to protect the second source metal layer SDL2. The second passivation layer PAS2 may include an inorganic layer. For example, the second passivation layer PAS2 may include one of a silicon nitride layer, a silicon oxynitride layer, a silicon oxide layer, a titanium oxide layer, and an aluminum oxide layer.

The third source metal layer SDL3 may be disposed on the second via layer VIA2. The third source metal layer SDL3 may include the third connection electrode CE3. The third connection electrode CE3 may be connected to a first pixel electrode AND1 penetrating the third passivation layer PAS3 and the third via layer VIA3. Accordingly, the third connection electrode CE3 may electrically connect the first pixel electrode AND1 with the second connection electrode CE2. The third source metal layer SDL3 may be a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The third via layer VIA3 may be disposed on the third source metal layer SDL3. The third via layer VIA3 may flatten the upper end portion of the third source metal layer SDL3. The third via layer VIA3 may include an organic layer such as an acryl resin, an epoxy resin, a phenolic resin, a polyamide resin, a polyimide resin, or the like.

The third passivation layer PAS3 may be disposed on the third via layer VIA3 to protect the third source metal layer SDL3. The third passivation layer PAS3 may include an inorganic layer. For example, the third passivation layer PAS3 may include one of a silicon nitride layer, a silicon oxynitride layer, a silicon oxide layer, a titanium oxide layer, and an aluminum oxide layer.

The fourth source metal layer SDL4 may be disposed on the third passivation layer PAS3. The fourth source metal layer SDL4 may include the first pixel electrode AND1 and a first cathode electrode CAT1. The first pixel electrode AND1 may electrically connect the third connection electrode CE3 to the second pixel electrode AND2. The fourth source metal layer SDL4 may be a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The anode layer ANDL may be disposed on the fourth source metal layer SDL4. The anode layer ANDL may include a second pixel electrode AND2 and a second cathode electrode CAT2. The anode layer ANDL may include a transparent conductive material (TCO) such as indium tin oxide (ITO), indium zinc oxide (IZO), and indium tin zinc oxide (ITZO).

The fourth passivation layer PAS4 may be disposed on the edge portion of a pixel electrode AND, the edge portion of a cathode electrode CAT, and the edge portion of the front pad portion FPD. The fourth passivation layer PAS4 may include an inorganic layer. For example, the fourth passivation layer PAS4 may include one of a silicon nitride layer, a silicon oxynitride layer, a silicon oxide layer, a titanium oxide layer, and an aluminum oxide layer. The fourth passivation layer PAS4 may expose a part of the top surface of the pixel electrode AND without covering it. The fourth passivation layer PAS4 may expose a portion of the top surface of the cathode electrode CAT and not cover the entirety.

The pixel electrode AND may receive a driving current from the pixel circuit, and a light emitting element ED may emit light having a certain luminance based on a magnitude of the driving current and a period in which the driving current flows.

The light emitting element ED may be connected between the pixel electrode AND and the cathode electrode CAT. The light emitting element ED may be disposed on the anode layer ANDL. The light emitting element ED may be the micro light emitting diode (micro LED) of a flip chip type in which a first contact electrode CTE1 is connected to the pixel electrode AND and a second contact electrode CTE2 is connected to the cathode electrode CAT, but embodiments are not limited thereto. The light emitting element ED may include an inorganic material such as GaN. In the light emitting element ED, each of the length thereof in the first direction (e.g., X-axis direction), the length thereof in the second direction (e.g., Y-axis direction), and the length thereof in the third direction (e.g., Z-axis direction) may be several to several hundred For example, in the light emitting element ED, each of the length thereof in the first direction (e.g., X-axis direction), the length thereof in the second direction (e.g., Y-axis direction), and the length thereof in the third direction (e.g., Z-axis direction) may be about 100 μm or less.

The light emitting element ED may be formed by growing on a semiconductor substrate such as a silicon wafer. For example, the light emitting elements ED may be moved onto the pixel electrode AND and the cathode electrode CAT of the substrate SUB on the silicon wafer. For another example, the light emitting elements ED may be moved onto the pixel electrode AND and the cathode electrode CAT by an electrostatic method by using an electrostatic head or a stamp method by using an elastic polymer material such as polydimethylsiloxane (PDMS) or silicon as a transfer substrate.

The light emitting element ED may be a light emitting structure including a base substrate SPUB, an n-type semiconductor NSEM, an active layer MQW, a p-type semiconductor PSEM, the first contact electrode CTE1, and the second contact electrode CTE2. For example, the base substrate SPUB may be a sapphire substrate, but embodiments are not limited thereto.

An n-type semiconductor NSEM may be disposed on a surface of the base substrate SPUB. For example, the n-type semiconductor NSEM may be disposed on the bottom surface of the base substrate SPUB. The n-type semiconductor NSEM may include GaN doped with an n-type conductivity-type dopant such as Si, Ge, and Sn.

The active layer MQW may be disposed on a portion of a surface of the n-type semiconductor NSEM. The active layer MQW may include a material having a single quantum well structure or a multiple quantum well structure. In case that the active layer MQW includes a material having a multiple quantum well structure, the active layer MQW may have the structure in which well layers and barrier layers are alternately laminated. For example, the well layer may include InGaN, and the barrier layer may include GaN or AlGaN, but embodiments are not limited thereto. For another example, the active layer MQW may have a structure in which a semiconductor material having a large band gap energy and a semiconductor material having a low band gap energy are alternately stacked. For yet another example, the active layer MQW may include different Group 3 to Group 5 semiconductor materials according to the wavelength band of the emitted light.

The p-type semiconductor PSEM may be disposed on a surface of the active layer MQW. The p-type semiconductor PSEM may include GaN doped with a p-type conductivity-type dopant such as Mg, Zn, Ca, Se, and Ba.

The first contact electrode CTE1 may be disposed on a surface of the p-type semiconductor PSEM, and the second contact electrode CTE2 may be disposed on another portion of a surface of the n-type semiconductor NSEM. The second contact electrode CTE2 may be spaced apart from the active layer MQW.

The first contact electrode CTE1 and the pixel electrode AND may be adhered to each other through a conductive adhesive member such as an anisotropic conductive film or an anisotropic conductive paste. For another example, the first contact electrode CTE1 and the pixel electrode AND may be adhered to each other by a soldering process. The second contact electrode CTE2 and the cathode electrode CAT may be adhered to each other by a conductive adhesive member or a soldering process.

The front pad portion FPD may be disposed on the first surface FS of the substrate SUB. The front pad portion FPD may include first to fifth portions SPD1, SPD2, SPD3, SPD4, and SPD5. The first portion SPD1 and the first connection electrode CE1 of the first source metal layer SDL1 may be formed of the same material and in the same process. The second portion SPD2 may be disposed on the first portion SPD1. The second portion SPD2 and the second connection electrode CE2 of the second source metal layer SDL2 may be formed of the same material and in the same process. The third portion SPD3 may be disposed on the second portion SPD2. The third portion SPD3 and the third connection electrode CE3 of the third source metal layer SDL3 may be formed of the same material and in the same process. The fourth portion SPD4 may be disposed on the third portion SPD3. The fourth portion SPD4 and the first pixel electrode AND1 of the fourth source metal layer SDL4 may be formed of the same material and in the same process. The fifth portion SPD5 may be disposed on the fourth portion SPD4. The fifth portion SPD5 and the second pixel electrode AND2 of the anode layer ANDL may be formed of the same material and in the same process. The fourth passivation layer PAS4 may be disposed on an edge portion of the front pad portion FPD and may be opened on a portion of the top surface of the front pad portion FPD. The front pad portion FPD may be exposed by the fourth passivation layer PAS4 to be connected to the side surface connection line SCL.

The trench portion TRC may be disposed at the edge portion of the non-display area NDA. The trench portion TRC may be formed such that a portion of a thin film transistor layer TFTL is recessed. The first via layer VIA1 may not be disposed on the trench portion TRC and the trench portion TRC may have a trench structure between the front pad portion FPD and the light emitting element ED. The height of the trench portion TRC may be lower than the height of the front pad portion FPD and the height of the light emitting element ED. For example, each of the heights of the trench portion TRC, the front pad portion FPD, and the light emitting element ED may be measured based on the substrate SUB. Accordingly, the trench portion TRC may prevent the front protective film from overflowing onto the front pad portion FPD beyond the trench portion TRC during the formation of the front protective film.

The side surface connection line SCL may be disposed on a side surface of the display device 10. The side surface connection line SCL may cover a rear surface edge portion of the display device 10, a side surface of the display device 10, and a top surface edge portion of the display device 10. An end portion of the side surface connection line SCL may be connected to the rear pad portion BPD, and another end portion of the side surface connection line SCL may be connected to the front pad portion FPD. The side surface connection line SCL may pass through the fourth via layer VIA4, the fifth passivation layer PASS, the substrate SUB, the buffer layer BF, the first and second gate insulating layers GI1 and GI2, and the interlayer insulating layer ILD, and the side surface of the fourth passivation layer PAS4.

The rear pad portion BPD may be disposed on the second surface BS of the substrate SUB. The rear pad portion BPD may be electrically connected to the front pad portion FPD through the side surface connection line SCL. The rear pad portion BPD may be electrically connected to the contact pad portion CPD through the lead line BCL.

The contact pad portion CPD may be integral with the rear pad portion BPD and the lead line BCL. The contact pad portion CPD, the rear pad portion BPD, and the lead line BCL may be formed as a single layer or multiple layers made of any one of molybdenum (Mo), aluminum (Al), chrome (Cr), gold (Au), titanium (Ti), nickel (Ni), neodymium (Nd), and copper (Cu), or an alloy thereof.

The fourth via layer VIA4 may cover the lead line BCL, and may expose the contact pad portion CPD and the rear pad portion BPD. The fourth via layer VIA4 may planarize the rear surface of the substrate SUB. The fourth via layer VIA4 may include an organic layer such as an acryl resin, an epoxy resin, a phenolic resin, a polyamide resin, a polyimide resin, or the like.

The fifth passivation layer PASS may be disposed on the rear surface of the fourth via layer VIA4 to protect the contact pad portion CPD, the rear pad portion BPD, and the lead line BCL. The fifth passivation layer PASS may include an inorganic layer. For example, the fifth passivation layer PASS may include one of a silicon nitride layer, a silicon oxynitride layer, a silicon oxide layer, a titanium oxide layer, and an aluminum oxide layer.

An overcoat layer OC may be disposed on the first surface FS, the first chamfer surface CS1, the first side surface SS1, the third chamfer surface CS3, and the second surface BS of the substrate SUB. The overcoat layer OC may cover the side surface connection line SCL. The overcoat layer OC may include an organic layer such as an acryl resin, an epoxy resin, a phenolic resin, a polyamide resin, a polyimide resin, or the like.

The circuit board 200 may be disposed on the rear surface of the fifth passivation layer PAS5. The circuit board 200 may be attached to the fifth passivation layer PAS5 by using a conductive adhesive member such as an anisotropic conductive film. The circuit board 200 may supply a voltage or a signal to the front pad portion FPD disposed on the first surface FS of the substrate SUB through the contact pad portion CPD, the lead line BCL, the rear pad portion BPD, and the side surface connection line SCL. The circuit board 200 may mount the display driver 300 on the second surface BS of the substrate SUB. The circuit board 200 may transmit a signal of the display driver 300 to the pixels SP.

A connection film CAM may attach the circuit board 200 to the contact pad portion CPD. For example, the connection film CAM may include an anisotropic conductive film. In case that the connection film CAM includes the anisotropic conductive film, the connection film CAM may have conductivity in an area in which the contact pad portion CPD and the circuit board 200 are in contact with each other, and may electrically connect the circuit board 200 to the contact pad portion CPD.

The display device 10 may include the rear pad portion BPD disposed on the second surface BS of the substrate SUB, the front pad portion FPD disposed on the first surface FS of the substrate SUB, and the side surface connection line SCL electrically connecting the rear pad portion BPD with the front pad portion FPD, so that the circuit board or the flexible film disposed on the side surface of the substrate SUB may be omitted, and a bezel-less display device may be implemented.

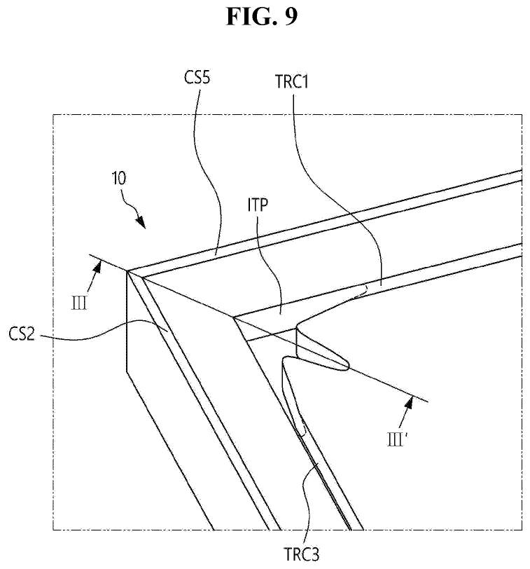

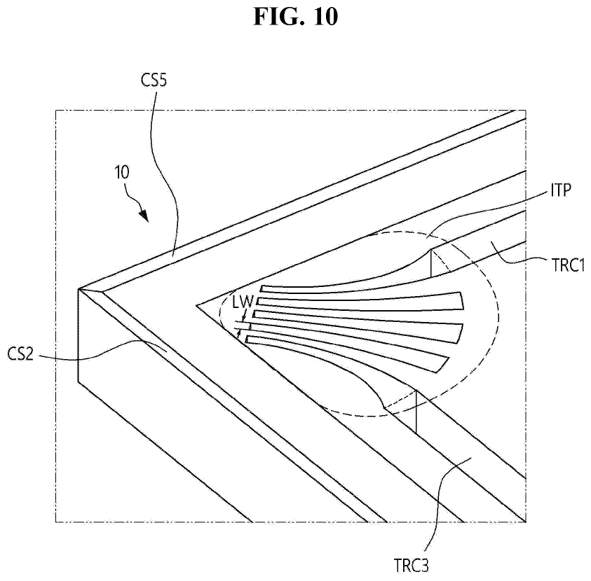

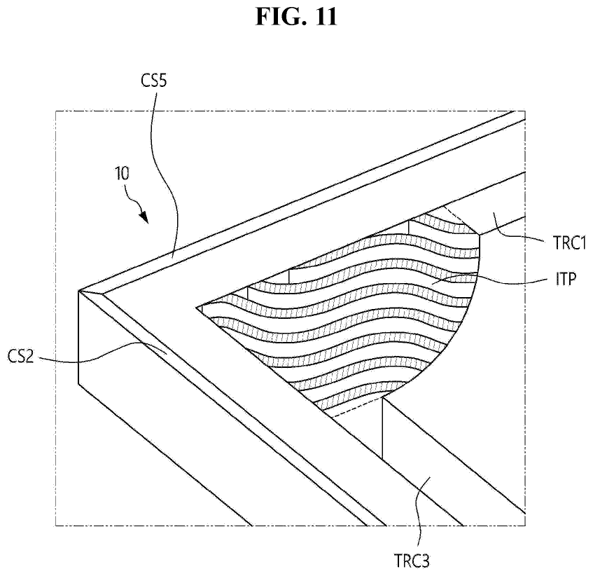

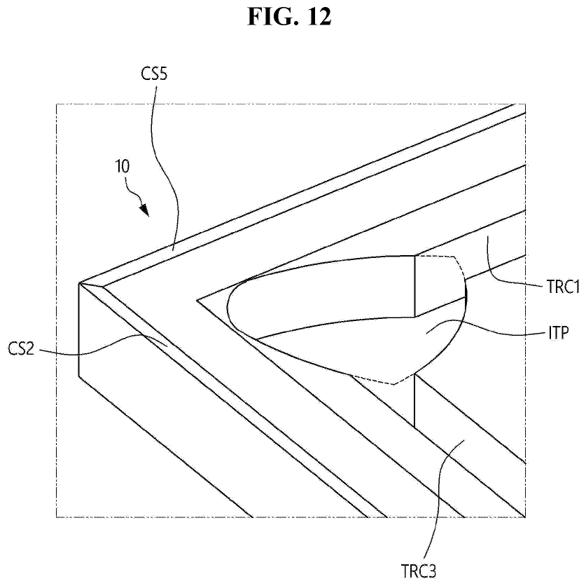

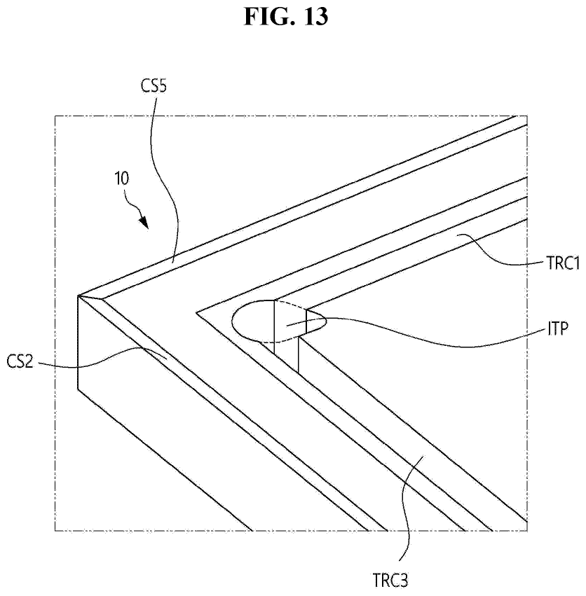

FIG. 9 is a schematic perspective view of one example of an engraved pattern portion in a display device according to an embodiment, and FIG. 10 is a schematic perspective view of another example of an engraved pattern portion in a display device according to an embodiment. FIG. 11 is a schematic perspective view of yet another example of an engraved pattern portion in a display device according to an embodiment, FIG. 12 is a schematic perspective view of still yet another example of an engraved pattern portion in a display device according to an embodiment, and FIG. 13 is a schematic perspective view of still yet another example of an engraved pattern portion in a display device according to an embodiment.

Referring to FIGS. 9 to 13, the engraved pattern portion ITP may be disposed at a corner portion of the non-display area NDA. The engraved pattern portion ITP may be formed to be recessed from the top surface of the non-display area NDA. As the engraved pattern portion ITP accommodates the corner portion of the front protective film, the thickness of the corner portion of the front protective film may be increased. For example, the engraved pattern portion ITP may be formed by recessing a part of the thin film transistor layer TFTL. In another example, the engraved pattern portion ITP may be formed by recessing a part of a substrate SUB. The engraved pattern portion ITP may be disposed at the upper left corner portion of the display device 10, but embodiments are not limited thereto. The engraved pattern portion ITP may be disposed at/in at least one of the corner portions of the display device 10.

In FIG. 9, the engraved pattern portion ITP may have a bird's foot shape. A part of the engraved pattern portion ITP may extend toward the first trench portion TRC1 and may be connected to the first trench portion TRC1. Another part of the engraved pattern portion ITP may extend toward the third trench portion TRC3 and may be connected to the third trench portion TRC3. Still another part of the engraved pattern portion ITP may extend toward the display area DA. The first trench portion TRC1 may be adjacent to the fifth chamfer surface CS5, and the third trench portion TRC3 may be adjacent to the second chamfer surface CS2. The fifth chamfer surface CS5 may be formed by a chamfer process.

In FIG. 10, the engraved pattern portion ITP may include grooves, and the grooves may have a spread shape or a fan-out shape. Each of the grooves may extend from a corner portion of the substrate SUB toward a central portion of the substrate SUB. The grooves may be adjacent to each other in an area adjacent to the corner portion of the substrate SUB, and may be spaced apart from each other as they are further away from the corner portion of the substrate SUB. The width of the groove may increase as it gets closer to the central portion of the substrate SUB. A width LW of the groove may be about 10 μm or more, but embodiments are not limited thereto. A groove disposed on a side of the grooves may be connected to the first trench portion TRC1, and a groove disposed on another side opposite to a side may be connected to the third trench portion TRC3. As the grooves of the engraved pattern portion ITP accommodates the corner portion of the front protective film, the thickness of the corner portion of the front protective film may be increased.

In FIG. 11, the engraved pattern portion ITP may include grooves, and the grooves may have a wave shape. Each of the grooves may extend from a corner portion of the substrate SUB toward a central portion of the substrate SUB. The width of the groove may be about 10 μm or more, but embodiments are not limited thereto. A groove disposed on a side of the grooves may be connected to the first trench portion TRC1, and a groove disposed on another side opposite to a side may be connected to the third trench portion TRC3. As the grooves of the engraved pattern portion ITP accommodates the corner portion of the front protective film, the thickness of the corner portion of the front protective film may be increased.

In FIG. 12, the engraved pattern portion ITP may have a parabolic shape. A side of the engraved pattern portion ITP may be connected to the first trench portion TRC1 and another side of the engraved pattern portion ITP opposite to the side thereof may be connected to the third trench portion TRC3. As the engraved pattern portion ITP accommodates the corner portion of the front protective film, the thickness of the corner portion of the front protective film may be increased.

In FIG. 13, the engraved pattern portion ITP may have a needle hole shape. The depth of the central portion of the engraved pattern portion ITP may be greater than the depth of the edge portion of the engraved pattern portion ITP, but embodiments are not limited thereto. A side of the engraved pattern portion ITP may be connected to the first trench portion TRC1 and another side opposite to the side may be connected to the third trench portion TRC3. As the engraved pattern portion ITP accommodates the corner portion of the front protective film, the thickness of the corner portion of the front protective film may be increased.

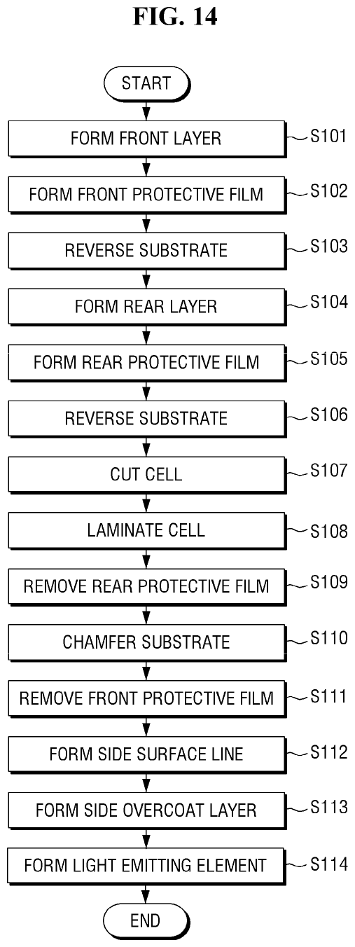

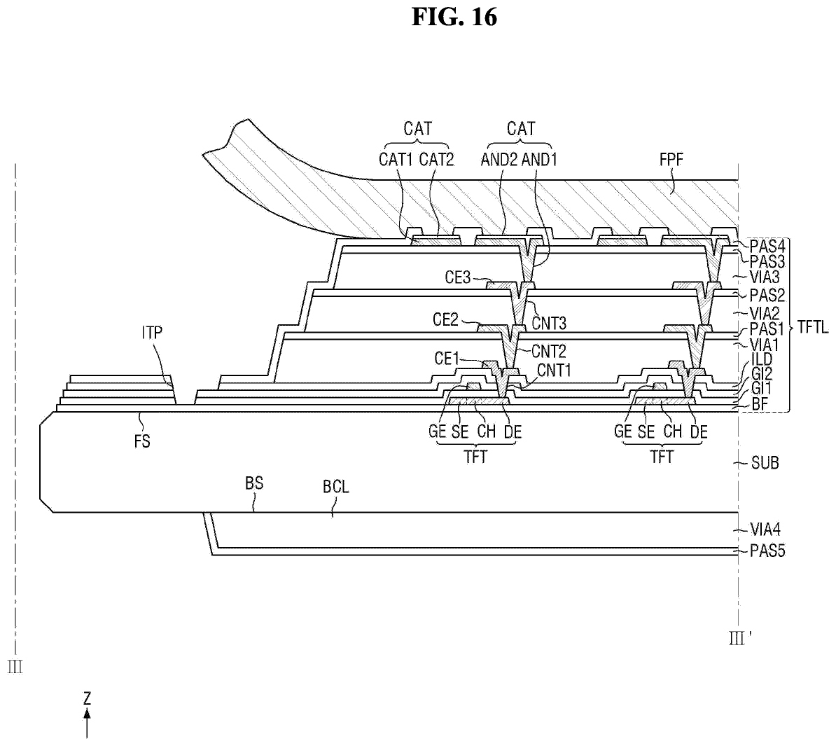

FIG. 14 is a flowchart illustrating a process for manufacturing a display device according to an embodiment. FIG. 15 is a schematic cross-sectional view taken along line III-III′ of FIG. 9, showing a process for manufacturing a display device according to an embodiment, and FIG. 16 shows a process of removing a front protective film in a manufacturing process of a display device of FIG. 15.

Referring to FIGS. 14 to 16, in the process of manufacturing the display device 10, a front layer may be formed on a surface of the substrate SUB (in a step S101). For example, the front layer may include a thin film transistor layer TFTL, but embodiments are not limited thereto. For example, a buffer layer BF, an active layer ACTL, a first gate insulating layer GI1, a first gate layer GTL1, a second gate insulating layer GI2, second gate layer GTL2, an interlayer insulating layer ILD, a first source metal layer SDL1, a first via layer VIA1, a first passivation layer PAS1, a second source metal layer SDL2, a second via layer VIA2, a second passivation layer PAS2, a third source metal layer SDL3, a third via layer VIA3, a third passivation layer PAS3, a fourth source metal layer SDL4, an anode layer ANDL, and a fourth passivation layer PAS4 may be sequentially stacked on the substrate SUB.

In FIG. 15, a front protective film FPF may be disposed on the thin film transistor layer TFTL (in a step S102). The front protective film FPF may protect the thin film transistor layer TFTL in the manufacturing process of the display device 10. For example, front protective film FPF may be formed by an inkjet printing process. The front protective film FPF may include an acrylic-based low-viscosity chemical solution, but embodiments are not limited thereto. A corner portion of the front protective film FPF may be inserted into the engraved pattern portion ITP, and an edge portion of the front protective film FPF may be inserted into the trench portion TRC. As the engraved pattern portion ITP accommodates the corner portion of the front protective film FPF, the thickness of the corner portion of the front protective film FPF may be increased. As the trench portion TRC accommodates the edge portion of the front protective film FPF, the thickness of the edge portion of the front protective film FPF may be increased. For example, as the thickness of the corner portion or edge portion of the front protective film FPF increases, the contact angle may increase and the surface tension may decrease. In the process of forming the front protective film FPF, the trench portion TRC may prevent the front protective film FPF from overflowing onto the front pad portion FPD.

In order to form a rear layer, the substrate SUB may be reversed (in a step 103). Accordingly, the front layer of the display device 10 may support the substrate SUB, and the front protective film FPF may protect the front layer of the display device 10.

The rear layer may be formed on the other surface opposite to the surface of the substrate SUB (in a step S104). For example, the rear layer may include a lead line BCL, a rear pad portion BPD, a contact pad portion CPD, a fourth via layer VIA4, a fifth passivation layer PASS, and a circuit board 200.

In FIG. 15, a rear protective film BPF may be formed on the rear layer (in a step S105).

The rear protective film BPF may protect the rear layer during the manufacturing process of the display device 10. For example, the rear protective film BPF may be formed by an inkjet printing process. The rear protective film BPF may include an acrylic-based low-viscosity liquid, but embodiments are not limited thereto.

In order to cut the cell, the substrate SUB may be reversed (in a step S106). Accordingly, the substrate SUB may support the front layer of the display device 10 and the rear protective film BPF may protect the rear layer.

Cells may be formed in the same process. The cells may be cut after the front layer and the rear layer are formed (in a step S107). For example, each of the cells may be manufactured as the display device 10.

A lamination process may be performed on the cut cell (in a step S108). The laminated film may cover the upper surface of the cell or display device 10.

The rear protective film BPF may be removed from the display device 10 (in a step 109).

The edge portion of the substrate SUB may be obliquely cut by a chamfer process (in a step S110). The first to fifth chamfer surfaces CS1, CS2, CS3, CS4, and CS5 may be formed by the chamfer process.

In FIG. 16, the front protective film FPF may be removed from the display device 10 (in a step S111). In case that the engraved pattern portion ITP does not exist, the thickness of the corner portion of the front protective film FPF decreases, and the front protective film FPF is incompletely peeled off, so that a portion of the front protective film FPF may remain. Remaining or unpeeled portions of the front protective film FPF may degrade reliability of the display device 10. Accordingly, since the corner portion of the front protective film FPF is disposed in the engraved pattern portion ITP, the contact angle of the corner portion of the front protective film FPF may be increased and the release force of the front protective film FPF may be dispersed. The engraved pattern portion ITP may prevent incomplete peeling of the front protective film FPF, and the front protective film FPF may be readily peeled off from the display device 10.

The side surface connection line SCL may be formed on the side of the substrate SUB (in a step S112). The side surface connection line SCL may electrically connect the front pad portion FPD and the rear pad portion BPD.

The overcoat layer OC may cover the side surface connection line SCL (in a step S113). The overcoat layer OC may include an organic layer such as an acryl resin, an epoxy resin, a phenolic resin, a polyamide resin, a polyimide resin, or the like.

The light emitting elements ED may be formed on the pixel electrode AND and the cathode electrode CAT (in a step S114). The light emitting element ED may be the micro light emitting diode (micro LED) of a flip chip type in which a first contact electrode CTE1 is connected to the pixel electrode AND and a second contact electrode CTE2 is connected to the cathode electrode CAT, but embodiments are not limited thereto.

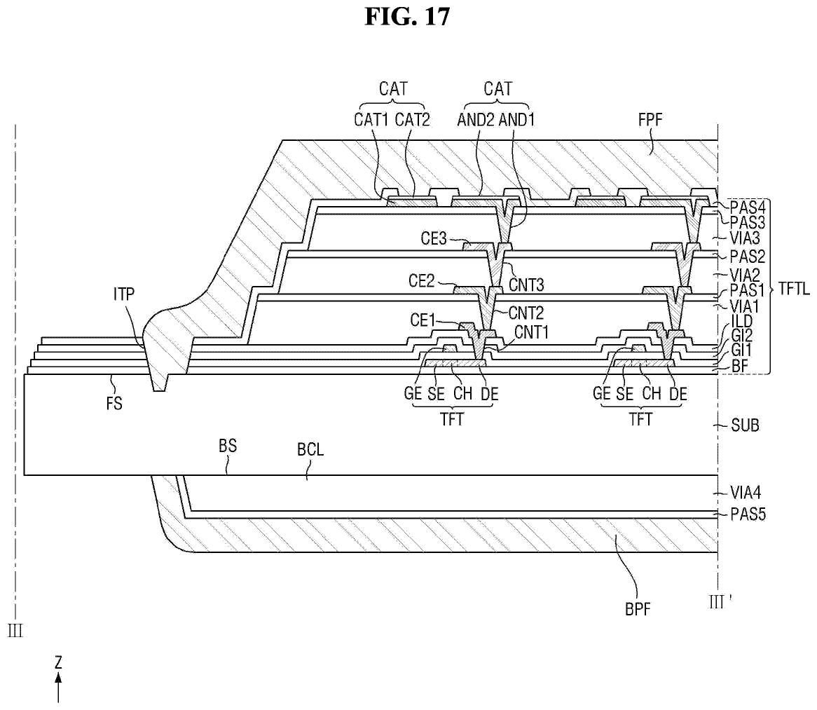

FIG. 17 is a schematic cross-sectional view taken along line III-III′ of FIG. 9, showing a process for manufacturing a display device according to another embodiment. The display device of FIG. 17 has a different configuration of the engraved pattern portion ITP from the display device of FIG. 15, and the same configuration as the above-described configuration will be briefly described or omitted for descriptive convenience.

Referring to FIG. 17, the engraved pattern portion ITP may be formed by recessing a part of the substrate SUB. Accordingly, the engraved pattern portion ITP may be formed by penetrating a part of the fourth passivation layer PAS4, the interlayer insulating layer ILD, the second gate insulating layer GI2, the first gate insulating layer GI1, the buffer layer BF, and the substrate SUB. As the engraved pattern portion ITP accommodates the corner portion of the front protective film, the thickness of the corner portion of the front protective film may be increased and the contact angle of the corner portion of the front protective film FPF may be increased. Accordingly, the release force of the front protective film FPF may be dispersed, so that the front protective film FPF may be readily peeled from the display device 10.

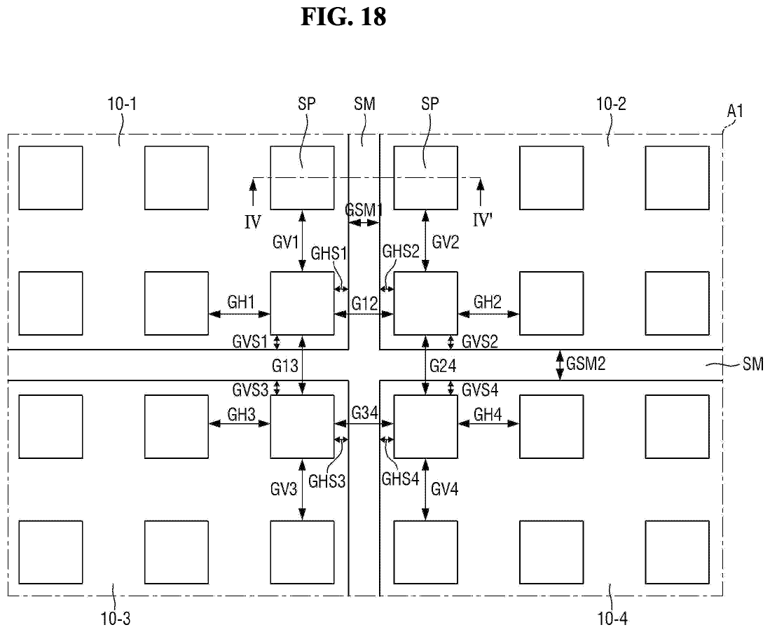

FIG. 18 is an enlarged schematic view of region A1 of FIG. 1.

Referring to FIG. 18, the coupling area SM may have a planar shape of the Chinese character ‘ten’, a cross, or a plus sign in a central area of the tiled display device TD adjacent to the first to fourth display devices 10-1, 10-2, 10-3 and 10-4.

The first to fourth display devices 10-1, 10-2, 10-3 and 10-4 may display an image by including the pixels SP arranged in a matrix form in the first direction (e.g., X-axis direction) and the second direction (e.g., Y-axis direction). The minimum distance between the pixels SP of the first display device 10-1 adjacent in the first direction (e.g., X-axis direction) may be defined as a first horizontal separation distance GH1, and the minimum distance between the pixels SP of the second display device 10-2 adjacent in the first direction (e.g., X-axis direction) may be defined as a second horizontal separation distance GH2. The first horizontal separation distance GH1 and the second horizontal separation distance GH2 may be substantially the same as each other.

The coupling area SM may be disposed between the pixel SP of the first display device 10-1 and the pixel SP of the second display device 10-2 adjacent in the first direction (e.g., X-axis direction). A minimum distance G12 between the pixel SP of the first display device 10-1 and the pixel SP of the second display device 10-2 may be the sum of a minimum distance GHS1 between the pixel SP of the first display device 10-1 and the coupling area SM in the first direction (e.g., X-axis direction), a minimum distance GHS2 between the pixel SP of the second display device 10-2 and the coupling area SM in the first direction (e.g., X-axis direction), and a width GSM1 of the coupling area SM in the first direction (e.g., X-axis direction).

The minimum distance G12 between the pixel SP of the first display device 10-1 and the pixel SP of the second display device 10-2, the first horizontal separation distance GH1, and the second horizontal separation distance GH2 may be substantially the same as each other. For example, the minimum distance GHS1 between the pixel SP of the first display device 10-1 and the coupling area SM in the first direction (e.g., X-axis direction) may be smaller than the first horizontal separation distance GH1, and the minimum distance GHS2 between the pixel SP of the second display device 10-2 and the coupling area SM in the first direction (e.g., X-axis direction) may be smaller than the second horizontal separation distance GH2. For example, the width GSM1 of the coupling area SM in the first direction (e.g., X-axis direction) may be smaller than the first horizontal separation distance GH1 or the second horizontal separation distance GH2.

The minimum distance between the pixels SP of the third display device 10-3 adjacent in the first direction (e.g., X-axis direction) may be defined as a third horizontal separation distance GH3, and the minimum distance between the pixels SP of the fourth display device 10-4 adjacent in the first direction (e.g., X-axis direction) may be defined as a fourth horizontal separation distance GH4. The third horizontal separation distance GH3 and the fourth horizontal separation distance GH4 may be substantially the same as each other.

The coupling area SM may be disposed between the pixel SP of the third display device 10-3 and the pixel SP of the fourth display device 10-4 adjacent in the first direction (e.g., X-axis direction). A minimum distance G34 between the pixel SP of the third display device 10-3 and the pixel SP of the fourth display device 10-4 may be the sum of a minimum distance GHS3 between the pixel SP of the third display device 10-3 and the coupling area SM in the first direction (e.g., X-axis direction), a minimum distance GHS4 between the pixel SP of the fourth display device 10-4 and the coupling area SM in the first direction (e.g., X-axis direction), and the width GSM1 of the coupling area SM in the first direction (e.g., X-axis direction).

The minimum distance G34 between the pixel SP of the third display device 10-3 and the pixel SP of the fourth display device 10-4, the third horizontal separation distance GH3, and the fourth horizontal separation distance GH4 may be substantially the same as each other. For example, the minimum distance GHS3 between the pixel SP of the third display device 10-3 and the coupling area SM in the first direction (e.g., X-axis direction) may be smaller than the third horizontal separation distance GH3, and the minimum distance GHS4 between the pixel SP of the fourth display device 10-4 and the coupling area SM in the first direction (e.g., X-axis direction) may be smaller than the fourth horizontal separation distance GH4. For example, the width GSM1 of the coupling area SM in the first direction (e.g., X-axis direction) may be smaller than the third horizontal separation distance GH3 or the fourth horizontal separation distance GH4.

The minimum distance between the pixels SP of the first display device 10-1 adjacent in the second direction (e.g., Y-axis direction) may be defined as a first vertical separation distance GV1, and the minimum distance between the pixels SP of the third display device 10-3 adjacent in the second direction (e.g., Y-axis direction) may be defined as a third vertical separation distance GV3. The first vertical separation distance GV1 and the third vertical separation distance GV3 may be substantially the same as each other.

The coupling area SM may be disposed between the pixel SP of the first display device 10-1 and the pixel SP of the third display device 10-3 adjacent in the second direction (e.g., Y-axis direction). A minimum distance G13 between the pixel SP of the first display device 10-1 and the pixel SP of the third display device 10-3 may be the sum of a minimum distance GVS1 between the pixel SP of the first display device 10-1 and the coupling area SM in the second direction (e.g., Y-axis direction), a minimum distance GVS3 between the pixel SP of the third display device 10-3 and the coupling area SM in the second direction (e.g., Y-axis direction), and a width GSM2 of the coupling area SM in the second direction (e.g., Y-axis direction).

The minimum distance G13 between the pixel SP of the first display device 10-1 and the pixel SP of the third display device 10-3, the first vertical separation distance GV1, and the third vertical separation distance GV3 may be substantially the same as each other. For example, the minimum distance GVS1 between the pixel SP of the first display device 10-1 and the coupling area SM in the second direction (e.g., Y-axis direction) may be smaller than the first vertical separation distance GV1, and the minimum distance GVS3 between the pixel SP of the third display device 10-3 and the coupling area SM in the second direction (e.g., Y-axis direction) may be smaller than the third vertical separation distance GV3. For example, the width GSM2 of the coupling area SM in the second direction (e.g., Y-axis direction) may be smaller than the first vertical separation distance GV1 or the third vertical separation distance GV3.

The minimum distance between the pixels SP of the second display device 10-2 adjacent in the second direction (e.g., Y-axis direction) may be defined as a second vertical separation distance GV2, and the minimum distance between the pixels SP of the fourth display device 10-4 adjacent in the second direction (e.g., Y-axis direction) may be defined as a fourth vertical separation distance GV4. The second vertical separation distance GV2 and the fourth vertical separation distance GV4 may be substantially the same as each other.

The coupling area SM may be disposed between the pixel SP of the second display device 10-2 and the pixel SP of the fourth display device 10-4 adjacent in the second direction (e.g., Y-axis direction). A minimum distance G24 between the pixel SP of the second display device 10-2 and the pixel SP of the fourth display device 10-4 may be the sum of a minimum distance GVS2 between the pixel SP of the second display device 10-2 and the coupling area SM in the second direction (e.g., Y-axis direction), a minimum distance GVS4 between the pixel SP of the fourth display device 10-4 and the coupling area SM in the second direction (e.g., Y-axis direction), and the width GSM2 of the coupling area SM in the second direction (e.g., Y-axis direction).

The minimum distance G24 between the pixel SP of the second display device 10-2 and the pixel SP of the fourth display device 10-4, the second vertical separation distance GV2, and the fourth vertical separation distance GV4 may be substantially the same as each other. For example, the minimum distance GVS2 between the pixel SP of the second display device 10-2 and the coupling area SM in the second direction (e.g., Y-axis direction) may be smaller than the second vertical separation distance GV2, and the minimum distance GVS4 between the pixel SP of the fourth display device 10-4 and the coupling area SM in the second direction (e.g., Y-axis direction) may be smaller than the fourth vertical separation distance GV4. For example, the width GSM2 of the coupling area SM in the second direction (e.g., Y-axis direction) may be smaller than the second vertical separation distance GV2 or the fourth vertical separation distance GV4.

Accordingly, the minimum distance between the pixels SP of the display devices 10 adjacent to each other is substantially the same as the minimum distance between the pixels SP of each of the display devices 10, so that the coupling area SM may be prevented to be visible. The minimum distance between the pixels of the display devices 10 adjacent to each other may be substantially the same as the minimum distance between the pixels SP of each of the display devices 10, and the coupling area SM may not be visually recognized.

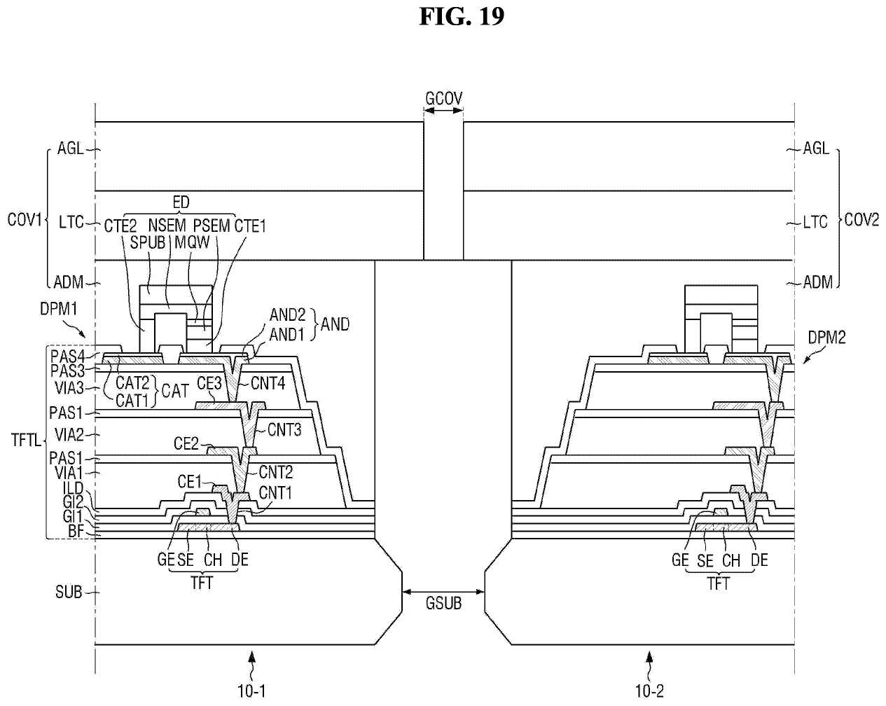

FIG. 19 is a schematic cross-sectional view taken along line IV-IV′ of FIG. 18.

Referring to FIG. 19, the first display device 10-1 may include a first display module DPM1 and a first front cover COV1. The second display device 10-2 may include a second display module DPM2 and a second front cover COV2.

Each of the first display module DPM1 and the second display module DPM2 may include the substrate SUB, the thin film transistor layer TFTL, and the light emitting elements ED.

The first front cover COV1 may be disposed on the substrate SUB. For example, the first front cover COV1 may protrude more than the substrate SUB in the first direction (e.g., X-axis direction) and the second direction (e.g., Y-axis direction). Accordingly, a distance GSUB between the substrate SUB of the first display device 10-1 and the substrate SUB of the second display device 10-2 may be greater than a distance GCOV between the first front cover COV1 and the second front cover COV2.

Each of the first front cover COV1 and the second front cover COV2 may include an adhesive member ADM, a light transmittance control layer LTC disposed on the adhesive member ADM, and an anti-glare layer AGL disposed on the light transmittance control layer LTC.

The adhesive member ADM of the first front cover COV1 may attach a light emitting element layer EML of the first display module DPM1 to the first front cover COV1. The adhesive member ADM of the second front cover COV2 may attach the light emitting element layer EML of the second display module DPM2 to the second front cover COV2. The adhesive member ADM may be a transparent adhesive member capable of transmitting light. For example, the adhesive member ADM may be an optically clear adhesive film or an optically clear resin.

The anti-glare layer AGL may reflect external light as it is and diffusely reflect external light to prevent deterioration of image visibility. The anti-glare layer AGL may improve a contrast ratio of images displayed by a first display device 10 and a second display device 20.

The light transmittance control layer LTC may reduce transmittance of external light or light reflected from the first display module DPM1 and the second display module DPM2. The light transmittance control layer LTC may prevent the distance GSUB between the substrate SUB of the first display module DPM1 and the substrate SUB of the second display module DPM2 from being visible from the outside.

The anti-glare layer AGL may be implemented as a polarizing plate, and the light transmittance control layer LTC may be implemented as a phase delay layer, but embodiments are not limited thereto.

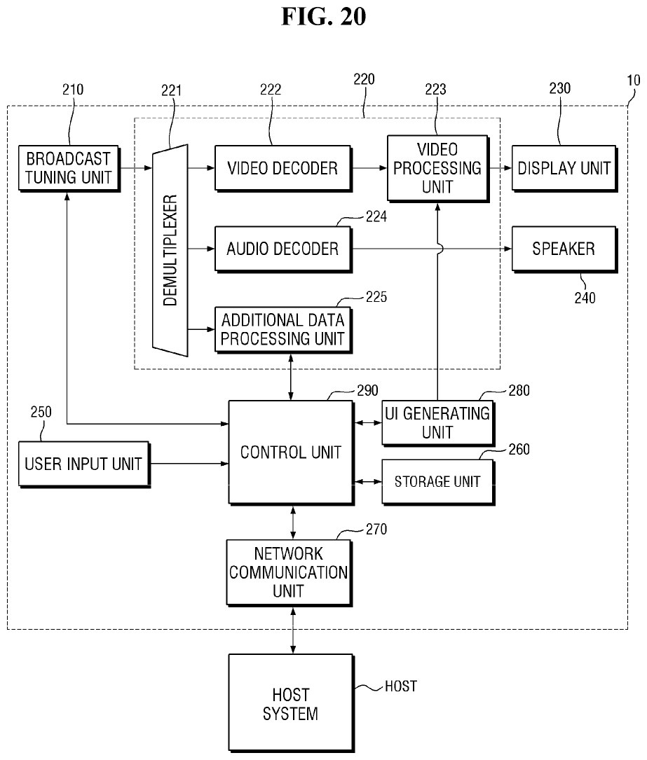

FIG. 20 is a block diagram illustrating a display system according to an embodiment.

Referring to FIG. 20, the tiled display device TD may include a host system HOST and display devices 10.

The host system HOST may be implemented as any one of a television system, a home theater system, a set-top box, a navigation system, a DVD player, a Blu-ray player, a personal computer (PC), a mobile phone system, and a tablet.

The host system HOST may receive a user's command in various formats. For example, the host system HOST may receive a command by a user's touch input. For another example, the host system HOST may receive a user's command by a keyboard input or a button input of a remote controller.

The host system HOST may receive original video data corresponding to the original image from the outside. The host system HOST may divide the original video data by the number of display devices. For example, corresponding to each of the first to fourth display devices 10-1, 10-2, 10-3 and 10-4, the host system HOST may divide the original video data into first video data corresponding to the first display device 10-1, second video data corresponding to the second display device 10-2, third video data corresponding to the third display device 10-3, and fourth video data corresponding to the fourth display device 10-4. The host system HOST may transmit the first video data to the first display device 10-1, transmit the second video data to the second display device 10-2, transmit the third video data to the third display device 10-3, and transmit the fourth video data to the fourth display device 10-4.

The first display device 10-1 may display a first image based on the first video data, the second display device 10-2 may display a second image based on the second video data, the third display device 10-3 may display a third image based on the third video data, and the fourth display device 10-4 may display a fourth image based on the fourth video data. Accordingly, the user may view the original image in which the first to fourth images displayed on the first to fourth display devices 10-1, 10-2, 10-3 and 10-4 are combined.

The display device 10 may include a broadcast tuning unit 210, a signal processing unit 220, a display unit 230, a speaker 240, a user input unit 250, a storage unit 260, a network communication unit 270, a UI generating unit 280, and a control unit 290.

The broadcast tuning unit 210 may receive a broadcast signal of a corresponding channel through an antenna pattern layer by tuning a channel frequency based on the control signal of the control unit 290. The broadcast tuning unit 210 may include a channel detection module and an RF module. The channel detection module may tune the channel frequency, and the RF module may demodulate the received broadcast signal.

The signal processing unit 220 may process the broadcast signal demodulated by the broadcast tuning unit 210 and output the processed result to the display unit 230 and the speaker 240. The signal processing unit 220 may include a demultiplexer 221, a video decoder 222, a video processing unit 223, an audio decoder 224, and an additional data processing unit 225.

The demultiplexer 221 may separate the demodulated broadcast signal into a video signal, an audio signal, and additional data. Each of the separated video signal, the audio signal, and additional data may be restored by the video decoder 222, the audio decoder 224, or the additional data processing unit 225. The video decoder 222, the audio decoder 224, and the additional data processing unit 225 may restore the broadcast signal by using a decoding format corresponding to an encoding format during broadcast signal transmission.

The video processing unit 223 may convert the decoded video signal to fit the vertical frequency, resolution, aspect ratio, and the like that meet the output standard of the display unit 230, and the speaker 240 may receive the decoded audio signal to output sound.

The display unit 230 may include a display panel on which an image is displayed and the display driver 300 that drives the display panel.

The user input unit 250 may receive a signal from the host system HOST. The user input unit 250 may receive data related to channel selection and user interface (UI) menu selection and manipulation from the host system HOST, as well as data related to communication between other display devices 10.

The storage unit 260 may store various software programs including an OS program, recorded broadcast programs, moving images, photos, and other data. For example, the storage unit 260 may include a storage medium such as a hard disk or a non-volatile memory.

The network communication unit 270 may perform short-distance communication between the host system HOST and other display devices 10. For example, the network communication unit 270 may include a communication module including an antenna pattern layer capable of implementing mobile communication, data communication, Bluetooth, RF, Ethernet, and the like.

The network communication unit 270 may transmit and receive a wireless signal with at least one of a base station, an external terminal, or a server on a mobile communication network implemented according to a technology standard or communication method for mobile communication (e.g., global system for mobile communication (GSM), code division multi access (CDMA), code division multi access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTE-A), 5G, and the like) through an antenna pattern layer.

The network communication unit 270 may transmit and receive a wireless signal in a communication network according to wireless Internet technologies through an antenna pattern layer. For example, wireless Internet technologies may be wireless LAN (WLAN), wireless-fidelity (Wi-Fi), wireless fidelity (Wi-Fi) direct, digital living network alliance (DLNA), wireless broadband (WiBro), world interoperability for microwave access (WiMAX), high speed downlink packet access (HSDPA), high speed uplink packet access (HSUPA), long term evolution (LTE), or long term evolution-advanced (LTE-A), and the antenna pattern layer may transmit and receive data according to at least one wireless Internet technology within a range including Internet technologies not listed above.

The UI generating unit 280 may generate a UI menu for communication between the host system HOST and other display devices 10, and may be implemented by an algorithm code and an OSD IC. The UI menu for communication with the host system HOST and other display devices 10 may be a menu for designating a counterpart digital TV for communication and selecting a certain function.

The control unit 290 may be in charge of overall control of the display device 10, and may be in charge of communication control with the host system HOST and other display devices 10. The control unit 290 may store a corresponding algorithm code for control, and may be implemented by a microcontroller unit (MCU) in which the stored algorithm code is executed.

The control unit 290 may control to transmit a corresponding control command and data to the host system HOST and other display devices 10 through the network communication unit 270 according to input and selection of the user input unit 250. The control unit 290 may receive a certain control command and data from the host system HOST and other display devices 10 and execute an operation according to the corresponding control command.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate comprising:
a first surface,
a second surface opposite to the first surface,
a first chamfer surface extending from a side of the first surface,
a second chamfer surface extending from a side of the second surface, and
a side surface connecting the first chamfer surface to the second chamfer surface;
a display area including a plurality of light emitting elements disposed on the first surface of the substrate;
a non-display area surrounding the display area on the first surface of the substrate;
an engraved pattern portion disposed at a corner portion of the non-display area and recessed from an upper surface of the non-display area; and
a trench portion disposed at a plurality of edge portions of the non-display area to surround the display area, the trench portion recessed toward the substrate.

2. The display device of claim 1, further comprising:
a front pad portion disposed at a part of the plurality of edge portions of the non-display area and electrically connected to the plurality of light emitting elements;
a rear pad portion disposed at an edge portion of the second surface of the substrate; and
a side surface connection line disposed on a side surface of the substrate and electrically connecting the front pad portion to the rear pad portion.

3. The display device of claim 2, further comprising:
an antistatic circuit disposed at an edge portion of the display area,
wherein the trench portion is disposed between the front pad portion and the antistatic circuit.

4. The display device of claim 2, wherein
the trench portion is disposed between the front pad portion and the plurality of light emitting elements, and
a height of the trench portion is lower than a height of the front pad portion and a height of each of the plurality of light emitting elements.

5. The display device of claim 2, further comprising:
a circuit board disposed on the second surface of the substrate and electrically connected to the rear pad portion.

6. The display device of claim 1, wherein
the trench portion includes a plurality of trench portions disposed at each of the plurality of edge portions of the non-display area, and
the engraved pattern portion is disposed between adjacent trench portions among the plurality of trench portions.

7. The display device of claim 1, further comprising:
a thin film transistor layer disposed on the first surface of the substrate and including a pixel circuit connected to a plurality of pixels,
wherein the engraved pattern portion is formed by recessing a part of the thin film transistor layer.

8. The display device of claim 1, further comprising:
a thin film transistor layer disposed on the first surface of the substrate and including a pixel circuit connected to a plurality of pixels,
wherein the engraved pattern portion is formed by recessing parts of the substrate and the thin film transistor layer.

9. The display device of claim 1, further comprising:
an antistatic layer disposed at an edge portion of the non-display area and electrically connected to a low potential line or a common voltage line,
wherein the trench portion is disposed between the antistatic layer and a plurality of pixels.

10. The display device of claim 1, wherein the engraved pattern portion includes at least one of bird's foot shape, a spread shape, a fan-out shape, a wave shape, a parabolic shape, a needle hole shape.

11. A display device comprising:
a substrate;
a thin film transistor layer disposed on the substrate;
a light emitting element disposed on the thin film transistor layer;
a display area including the light emitting element;
a non-display area surrounding the display area and including a plurality of edge portions;
an engraved pattern portion disposed at least one edge portion of the plurality of edge portions of the non-display area and recessed from an upper surface of the thin film transistor layer; and
a trench portion disposed at the plurality of edge portions of the non-display area and surrounding the display area, the trench portion recessed toward the substrate.

12. The display device of claim 11, further comprising:
a front pad portion disposed at a portion of the plurality of edge portions of the non-display area and electrically connected to the light emitting element; and
an antistatic circuit disposed at an edge portion of the display area,
wherein the trench portion is disposed between the front pad portion and the antistatic circuit.

13. The display device of claim 12, wherein
the trench portion is disposed between the front pad portion and the light emitting element, and
a height of the trench portion is lower than a height of the front pad portion and a height of the light emitting element.

14. The display device of claim 11, wherein
the trench portion includes a plurality of trench portions disposed at each of the plurality of edge portions of the non-display area, and
the engraved pattern portion is disposed between the plurality of trench portions.

15. The display device of claim 11, further comprising:
a thin film transistor layer disposed on a first surface of the substrate and including a pixel circuit connected to a plurality of pixels,
wherein the engraved pattern portion is formed by recessing a part of the thin film transistor layer.

16. The display device of claim 11, further comprising:
a thin film transistor layer disposed on a first surface of the substrate and including a pixel circuit connected to a plurality of pixels,
wherein the engraved pattern portion is formed by recessing parts of the substrate and the thin film transistor layer.

17. A tiled display device comprising:
a plurality of display devices that display an image; and
a coupling area disposed between the plurality of display devices,
wherein at least one of the plurality of display devices comprises:
a substrate comprising:
a first surface,
a second surface opposite to the first surface,
a first chamfer surface extending from a side of the first surface,
a second chamfer surface extending from a side of the second surface, and
a side surface connecting the first chamfer surface to the second chamfer surface;
a display area including a plurality of light emitting elements disposed on the first surface of the substrate;
a non-display area surrounding the display area on the first surface of the substrate;
an engraved pattern portion disposed at a corner portion of the non-display area and recessed from an upper surface of the non-display area; and
a trench portion disposed at a plurality of edge portions of the non-display area to surround the display area, the trench portion recessed toward the substrate.

18. The tiled display device of claim 17, wherein each of the plurality of light emitting elements is a micro light emitting diode of a flip chip type.

19. The tiled display device of claim 17, wherein at least one of the plurality of display devices further comprises:
a front pad portion disposed at a part of the plurality of edge portions of the non-display area and electrically connected to the plurality of light emitting elements;
a rear pad portion disposed at an edge portion of the second surface of the substrate;
a side surface connection line disposed on a side surface of the substrate and electrically connecting the front pad portion to the rear pad portion; and
a circuit board disposed on the second surface of the substrate and electrically connected to the rear pad portion.

20. The tiled display device of claim 17, wherein the plurality of display devices are arranged in a matrix form in M rows and N columns, where M and N are positive integers.
